(19) United States
(12) Patent Application Publication
(10) Pub. No.: US 2011/0123936 A1
(43) Pub. Date: May 26, 2011

(54) RESIST PATTERN COATING AGENT AND RESIST PATTERN-FORMING METHOD

(75) Inventors: Masafumi HORI, Tokyo (JP); Michihiro Mita, Tokyo (JP); Kouichi Fujiwara, Tokyo (JP); Katsuhiko Hieda, Tokyo (JP); Yoshikazu Yamaguchi, Tokyo (JP); Tomohiro Kakizawa, Tokyo (JP)

(73) Assignee: JSR Corporation, Tokyo (JP)

(21) Appl. No.: 13/022,560

(22) Filed: Feb. 7, 2011

Related U.S. Application Data
(63) Continuation of application No. PCT/JP2009/066418, filed on Sep. 18, 2009.

(30) Foreign Application Priority Data
Sep. 19, 2008 (JP) 2008-240545

(51) Int. Cl. G03F 7/20; C08L 61/28; C08L 33/26; C08L 41/00

(52) U.S. Cl. 430/324; 524/512; 524/502

(57) ABSTRACT

A resist pattern coating agent includes a hydroxyl group-containing resin, a solvent, and at least two compounds including at least two groups shown by a following formula (1), compounds including a group shown by a following formula (2), and compounds including a group shown by a following formula (4).

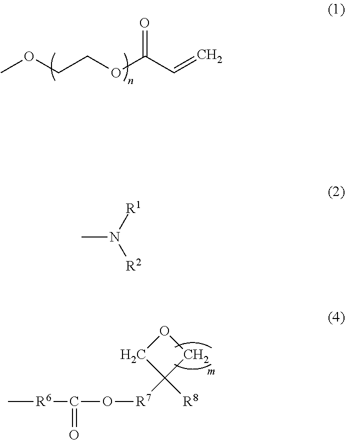

### CROSS-REFERENCE TO RELATED APPLICATIONS

The present application is a continuation application of International Application No. PCT/JP2009/066418, filed Sep. 18, 2009, which claims priority to Japanese Patent Application No. 2008-240545, filed Sep. 19, 2008. The contents of these applications are incorporated herein by reference in their entirety.

### BACKGROUND OF THE INVENTION

1. Field of the Invention

The present invention relates to a resist pattern coating agent and a resist pattern-forming method.

2. Discussion of the Background

In the field of microfabrication (e.g., production of integrated circuit devices), lithographic technology that enables microfabrication with a line width of 0.10 μm or less has been desired in order to achieve a higher degree of integration. A lithographic process has utilized near ultraviolet rays (e.g., i-line). However, it is considered to be difficult to implement sub-quarter-micrometer microfabrication using near ultraviolet rays. Therefore, use of radiation having a shorter wavelength has been studied in order to enable microfabrication with a line width of 0.10 μm or less. Examples of such radiation include deep ultraviolet rays (e.g., mercury line spectrum and excimer laser light), X-rays, electron beams, and the like. In particular, technology that utilizes KrF excimer laser light (wavelength: 248 nm) or ArF excimer laser light (wavelength: 193 nm) has attracted attention.

As a resist that is suitable for excimer laser light, various resists (chemically-amplified resists) that utilize a chemical amplification effect due to an acid-dissociable functional group-containing component and a component that generates an acid upon irradiation (exposure) (hereinafter may be referred to as “acid generator”) have been proposed. For example, a chemically-amplified resist that includes a resin containing a t-butyl ester group of a carboxylic acid or a t-butyl carbonate group of phenol, and an acid generator, has been proposed (see Japanese Patent Application Publication (KOKAI) No. 5-232704). This resist utilizes a phenomenon in which the t-butyl ester group or the t-butyl carbonate group contained in the resin dissociates due to an acid generated upon exposure to form an acidic group (e.g., carboxyl group or phenolic hydroxyl group), so that the exposed area of the resist film becomes readily soluble in an alkaline developer.

The lithographic process will be required to form a finer pattern (e.g., a fine resist pattern with a line width of about 45 nm). A pattern with a line width of less than 45 nm may be formed by reducing the wavelength of the light source of the exposure system, or increasing the numerical aperture (NA) of the lens. However, an expensive exposure system is required to reduce the wavelength of the light source. When increasing the numerical aperture (NA) of the lens, since the resolution and the depth of focus have a trade-off relationship, the depth of focus decreases as a result of increasing the resolution.

In recent years, liquid immersion lithography has been proposed as lithographic technology that makes it possible to solve the above problems (see Japanese Patent Application Publication (KOKAI) No. 10-303114, for example). In liquid immersion lithography, a high-refractive liquid medium (immersion liquid) (e.g., pure water or fluorine-containing inert liquid) is provided between the lens and the resist film formed on the substrate at least over the resist film during exposure. According to liquid immersion lithography, the optical space (path) is filled with a liquid (e.g., pure water) having a high refractive index (n) instead of an inert gas (e.g., air or nitrogen) so that the resolution can be increased without causing a decrease in depth of focus in the same manner as in the case of using a short-wavelength light source or a high NA lens. Since a resist pattern that exhibits a higher resolution and an excellent depth of focus can be inexpensively formed by liquid immersion lithography using a lens provided in an existing system, liquid immersion lithography has attracted attention, and is being put to practical use.

However, it is considered that liquid immersion lithography can only be applied up to 45 nmhp. Therefore, technical development toward a 32 nmhp generation has been conducted. In recent years, technology that forms a 32 nm line-and-space (LS) pattern by forming isolated line patterns or trench patterns shifted by a half pitch utilizing double patterning or double exposure has been proposed to deal with a demand for an increase in complexity and density of devices (see SPIE 2006, Vol. 6153 61531K, for example).

SPIE 2006, Vol. 6153 61531K discloses forming 32 nm lines at a pitch of 1:3, followed by etching. 32 nm lines are then formed at a pitch of 1:3 at positions shifted from the first-layer resist pattern by a half pitch, followed by etching to obtain 32 nm lines at a 1:1 pitch.

### SUMMARY OF THE INVENTION

According to one aspect of the present invention, a resist pattern coating agent includes a hydroxyl group-containing resin, a solvent, and at least two of compounds including at least two groups shown by a following formula (1), compounds including a group shown by a following formula (2), and compounds including a group shown by a following formula (4),

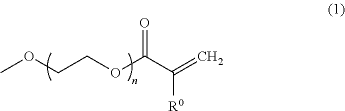

wherein R⁰ represents a hydrogen atom or a methyl group, and n is an integer from 0 to 10,

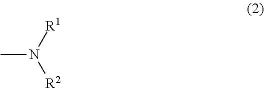

wherein R¹ and R² represent a hydrogen atom or a group shown by a following formula (3), provided that at least one of R¹ and R² represents a group shown by a formula (3),

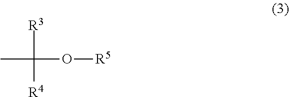

wherein R³ and R⁴ represent a hydrogen atom, an alkyl group having 1 to 6 carbon atoms, or an alkoxyalkyl group having 1 to 6 carbon atoms, or bond to form a ring having 2 to 10 carbon atoms, and R⁵ represents a hydrogen atom or an alkyl group having 1 to 6 carbon atoms,

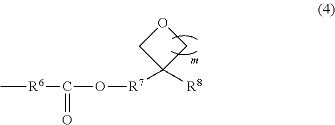

wherein each of R⁶ and R⁷ represents at least one of a single bond, a methylene group, a linear or branched alkylene group having 2 to 10 carbon atoms, and a divalent cyclic hydrocarbon group having 3 to 20 carbon atoms, R⁸ represents a linear or branched alkyl group having 1 to 10 carbon atoms or a monovalent cyclic hydrocarbon group having 3 to 20 carbon atoms, and m is 0 or 1.

According to another aspect of the present invention, a resist pattern-forming method includes providing a first positive-tone radiation-sensitive resin composition on a substrate to form a first resist pattern on the substrate. The above-mentioned resist pattern coating agent is applied to a first resist pattern. The resist pattern coating agent is baked or UV-cured. The resist pattern coating agent is washed to form an insolubilized resist pattern that is insoluble in a developer and a second positive-tone radiation-sensitive resin composition. The second positive-tone radiation-sensitive resin composition is provided on the substrate to form a second resist layer on the substrate on which the insolubilized resist pattern is formed. The second resist layer is selectively exposed through a mask. The second resist layer is developed to form a second resist pattern.

According to further aspect of the present invention, a resist pattern coating agent includes a hydroxyl group-containing resin, a solvent, and a compound including at least two groups shown by a following formula (1),

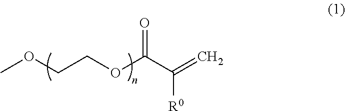

wherein R⁰ represents a hydrogen atom or a methyl group, and n is an integer from 0 to 10.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIG. 1 is a cross-sectional view showing an example of a step (1) of a resist pattern-forming method according to one embodiment of the invention (i.e., a state in which a first resist pattern is formed on a substrate);

FIG. 2 is a cross-sectional view showing an example of a step (1) of a resist pattern-forming method according to one embodiment of the invention (i.e., a state in which an insolubilized resist pattern is formed);

FIG. 3 is a schematic view showing an example of a step (1) of a resist pattern-forming method according to one embodiment of the invention (i.e., a state in which an insolubilized resist pattern is formed);

FIG. 4 is a cross-sectional view showing an example of a step (2) of a resist pattern-forming method according to one embodiment of the invention (i.e., a state in which a second resist layer is formed on an insolubilized resist pattern);

FIG. 5 is a schematic view showing an example of a step (3) of a resist pattern-forming method according to one embodiment of the invention (i.e., a state in which a second resist pattern is formed);

FIG. 6 is a schematic view showing another example of a step (3) of a resist pattern-forming method according to one embodiment of the invention (i.e., a state in which a second resist pattern is formed);

FIG. 7 is a schematic view showing still another example of a step (3) of a resist pattern-forming method according to one embodiment of the invention (i.e., a state in which a second resist pattern is formed); and

FIG. 8 is a side view showing an example of a step (3) of a resist pattern-forming method according to one embodiment of the invention (i.e., a state in which a second resist pattern is formed).

### DESCRIPTION OF THE EMBODIMENTS

The embodiments of the invention are described with reference to the accompanying drawings, wherein like reference numerals designate corresponding or identical elements throughout the various drawings. Note that the invention is not limited to the following embodiments. Various modifications and improvements may be made of the following embodiments without departing from the scope of the invention based on the knowledge of a person having ordinary skill in the art. Note that a first positive-tone radiation-sensitive resin composition and a second positive-tone radiation-sensitive resin composition may be referred to as “first resist material” and “second resist material”, respectively.

### I. Resist Pattern Coating Agent

A resist pattern coating agent according to one embodiment of the invention is used to form an insolubilized resist pattern that is insoluble in a developer and a second positive-tone radiation-sensitive resin composition in a resist pattern-forming method according to one embodiment of the invention. The resist pattern coating agent according to one embodiment of the invention includes a hydroxyl group-containing resin, a solvent, and a crosslinking agent. The term “crosslinking agent” used herein refers to at least two compounds selected from the group consisting of compounds including at least two groups shown by the following general formula (1) (hereinafter may be referred to as “crosslinking agent (1)”), compounds including a group shown by the following general formula (2) (hereinafter may be referred to as “crosslinking agent (2)”), and compounds including a group shown by the following general formula (4) (hereinafter may be referred to as “crosslinking agent (3)”), or a compound that includes only the crosslinking agent (1).

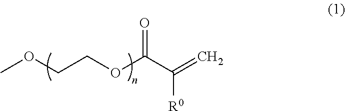

wherein R⁰ represents a hydrogen atom or a methyl group, and n is an integer from 0 to 10.

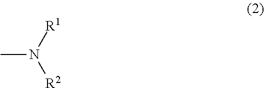

wherein R¹ and R² represent a hydrogen atom or a group shown by the following general formula (3), provided that at least one of R¹ and R² represents a group shown by the general formula (3),

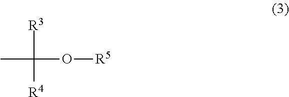

wherein R³ and R⁴ represent a hydrogen atom, an alkyl group having 1 to 6 carbon atoms, or an alkoxyalkyl group having 1 to 6 carbon atoms, or bond to form a ring having 2 to 10 carbon atoms, and R⁵ represents a hydrogen atom or an alkyl group having 1 to 6 carbon atoms.

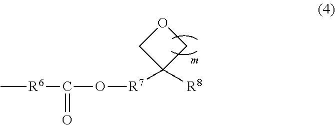

wherein R⁶ and R⁷ individually represent a single bond, a methylene group, a linear or branched alkylene group having 2 to 10 carbon atoms, or a divalent cyclic hydrocarbon group having 3 to 20 carbon atoms, R⁸ represents a linear or branched alkyl group having 1 to 10 carbon atoms or a monovalent cyclic hydrocarbon group having 3 to 20 carbon atoms, and m is 0 or 1.

### 1. Hydroxyl Group-Containing Resin

### (1) Monomer Component

The hydroxyl group-containing resin is obtained by polymerizing a monomer component including a monomer that includes at least one hydroxyl group (—OH) selected from the group consisting of an alcoholic hydroxyl group, a hydroxyl group derived from an organic acid (e.g., carboxylic acid), and a phenolic hydroxyl group.

(Monomer that Includes Alcoholic Hydroxyl Group)

Specific examples of the monomer that includes an alcoholic hydroxyl group include hydroxyalkyl (meth)acrylates such as 2-hydroxyethyl acrylate, 2-hydroxyethyl methacrylate, 2-hydroxypropyl acrylate, 2-hydroxypropyl methacrylate, 4-hydroxybutyl acrylate, 4-hydroxybutyl methacrylate, and glycerol monomethacrylate. Among these, 2-hydroxyethyl acrylate and 2-hydroxyethyl methacrylate are preferable. These monomers that include an alcoholic hydroxyl group may be used either individually or in combination.

The monomer that includes an alcoholic hydroxyl group is normally used in an amount of 5 to 90 mol %, and preferably 10 to 70 mol %, based on the total amount of the monomer component.

(Monomer that Includes Hydroxyl Group Derived from an Organic Acid (e.g., Carboxylic Acid))

Specific examples of the monomer that includes a hydroxyl group derived from an organic acid (e.g., carboxylic acid) include (meth)acrylic acid and (meth)acrylic acid derivatives such as monocarboxylic acids such as acrylic acid, methacrylic acid, crotonic acid, 2-succinoloylethyl(meth)acrylate, 2-maleinoloylethyl(meth)acrylate, 2-hexahydrophthaloylethyl(meth)acrylate, ω-carboxypolycaprolactone monoacrylate, monohydroxyethyl phthalate acrylate, an acrylic acid dimer, 2-hydroxy-3-phenoxypropyl acrylate, t-butoxy methacrylate, and t-butyl acrylate, and dicarboxylic acids such as maleic acid, fumaric acid, citraconic acid, mesaconic acid, and itaconic acid, and the like. Among these, acrylic acid, methacrylic acid, and 2-hexahydrophthaloylethyl methacrylate are preferable. These monomers that include a hydroxyl group derived from an organic acid (e.g., carboxylic acid) may be used either individually or in combination.

For example, ω-carboxy-polycaprolactone monoacrylate is commercially available as Aronix M-5300 (manufactured by Toagosei Co., Ltd.). An acrylic acid dimer is commercially available as Aronix M-5600 (manufactured by Toagosei Co., Ltd.). 2-Hydroxy-3-phenoxypropyl acrylate is commercially available as Aronix M-5700 (manufactured by Toagosei Co., Ltd.).

The monomer that includes a hydroxyl group derived from an organic acid (e.g., carboxylic acid) is normally used in an amount of 5 to 90 mol %, and preferably 10 to 60 mol %, based on the total amount of the monomer component.

(Monomer that Includes Phenolic Hydroxyl Group)

Specific examples of the monomer that includes a phenolic hydroxyl group include p-hydroxystyrene, m-hydroxystyrene, o-hydroxystyrene, α-methyl-p-hydroxystyrene, α-methyl-m-hydroxystyrene, α-methyl-o-hydroxystyrene, 2-allylphenol, 4-allylphenol, 2-allyl-6-methylphenol, 2-allyl-6-methoxyphenol, 4-allyl-2-methoxyphenol, 4-allyl-2,6-dimethoxyphenol, 4-allyloxy-2-hydroxybenzophenone, and the like. Among these, p-hydroxystyrene and α-methyl-p-hydroxystyrene are preferable.

As the monomer that includes a phenolic hydroxyl group, a monomer that includes an amide bond (amide group) in the molecule is preferable. Preferable examples of such a monomer include a monomer shown by the following general formula (6) (hereinafter referred to as “hydroxy(meth)acrylamide”).

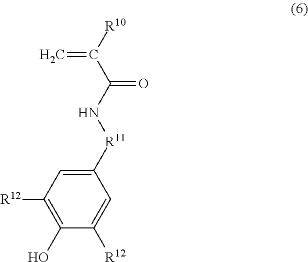

wherein R¹⁰ and R¹² individually represent a hydrogen atom or a methyl group, and R¹¹ represents a single bond or a divalent linear, branched, or cyclic hydrocarbon group.

Specific examples of the divalent linear, branched, or cyclic hydrocarbon group represented by R¹¹ in the general formula (6) include chain-like hydrocarbon groups such as a methylene group, an ethylene group, a propylene group (e.g., 1,3-propylene group and 1,2-propylene group), a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an octadecamethylene group, a nonadecamethylene group, an icosylene group, a 1-methyl-1,3-propylene group, a 2-methyl-1,3-propylene group, a 2-methyl-1,2-propylene group, a 1-methyl-1,4-butylene group, a 2-methyl-1,4-butylene group, an ethylidene group, a propylidene group, and a 2-propylidene group; monocyclic hydrocarbon groups such as a cycloalkylene group having 3 to 10 carbon atoms, such as a cyclobutylene group (e.g., 1,3-cyclobutylene group), a cyclopentylene group (e.g., 1,3-cyclopentylene group), a cyclohexylene group (e.g., 1,4-cyclohexylene group), and a cyclooctylene group (e.g., 1,5-cyclooctylene group); crosslinked cyclic hydrocarbon groups such as a dicyclic to tetracyclic hydrocarbon group having 4 to 30 carbon atoms, such as a norbornylene group (e.g., 1,4-norbornylene group and 2,5-norbornylene group), and an admantylene group (e.g., 1,5-admantylene group and 2,6-admantylene group); and the like. The hydroxy(meth)acrylamide is preferably at least one of hydroxyacrylanilide and hydroxymethacrylanilide in which R¹¹ represents a single bond, and particularly preferably p-hydroxymethacrylanilide.

The hydroxy(meth)acrylamide is normally used in an amount of 30 to 95 mol %, and preferably 40 to 90 mol %, based on the total amount of the monomer component.

A monomer that includes a specific functional group that can be converted into a phenolic hydroxyl group after copolymerization (hereinafter referred to as “specific functional group-containing monomer”) may also be used as the monomer that includes a phenolic hydroxyl group. Specific examples of the specific functional group-containing monomer include p-acetoxystyrene, α-methyl-p-acetoxystyrene, p-benzyloxystyrene, p-t-butoxystyrene, p-t-butoxycarbonyloxystyrene, p-t-butyldimethylsiloxystyrene, and the like. The specific functional group included in a resin obtained by copolymerizing the specific functional group-containing monomer may be easily converted into a phenolic hydroxyl group by an appropriate treatment (e.g., hydrolysis using hydrochloric acid).

The specific functional group-containing monomer is normally used in an amount of 5 to 90 mol %, and preferably 10 to 80 mol %, based on the total amount of the monomer component.

The monomer that includes an alcoholic hydroxyl group, the monomer that includes a hydroxyl group derived from an organic acid (e.g., carboxylic acid), and the monomer that includes a phenolic hydroxyl group are normally used within the above range based on the total amount of the monomer component. If the amount of the monomer that includes a hydroxyl group is too small, the resist pattern may shrink to only a small extent since a reaction site with the crosslinking agent described later may be insufficient. If the amount of the monomer that includes a hydroxyl group is too large, swelling may occur during development, so that the resist pattern may be buried.

### (Additional Monomer)

When the monomer component includes the hydroxy(meth)acrylamide, it is preferable that the monomer component further include a monomer shown by the following general formula (7).

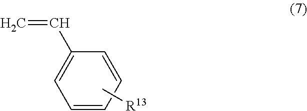

wherein R¹³ represents a hydrogen atom, an acetoxy group, a linear or branched alkyl group having 1 to 8 carbon atoms, or a linear or branched alkoxy group having 1 to 8 carbon atoms.

The linear or branched alkoxy group having 1 to 8 carbon atoms represented by R¹³ in the general formula (7) is preferably a t-butoxy group, an acetoxy group, or a 1-ethoxyethoxy group, and particularly preferably a t-butoxy group.

The monomer component may further include an additional monomer in order to control the hydrophilicity and the solubility of the resin. Examples of the additional monomer include aryl(meth)acrylates, dicarboxylic diesters, nitrile group-containing polymerizable compounds, amide bond-containing polymerizable compounds, vinyl compounds, allyl compounds, chlorine-containing polymerizable compounds, conjugated diolefins, and the like. Specific examples of the additional monomer include dicarboxylic diesters such as diethyl maleate, diethyl fumarate, and diethyl itaconate; aryl(meth)acrylates such as phenyl(meth)acrylate and benzyl(meth)acrylate; (meth)acrylates such as t-butyl(meth)acrylate and 4,4,4-trifluoro-3-hydroxy-1-methyl-3-trifluoromethyl-1-butyl(meth)acrylate; nitrile group-containing polymerizable compounds such as acrylonitrile and methacrylonitrile; amide bond-containing polymerizable compounds such as acrylamide and methacrylamide; fatty-acid vinyl compounds such as vinyl acetate; chlorine-containing polymerizable compounds such as vinyl chloride and vinylidene chloride; and conjugated diolefins such as 1,3-butadiene, isoprene, and 1,4-dimethylbutadiene. These additional monomers may be used either individually or in combination.

Preferable examples of the additional monomer include a compound shown by the following general formula (8).

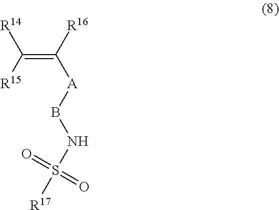

wherein R¹⁴ to R¹⁶ individually represent a hydrogen atom, an alkyl group having 1 to 10 carbon atoms, a hydroxymethyl group, a trifluoromethyl group, or a phenyl group, A represents a single bond, an oxygen atom, a carbonyl group, a carbonyloxy group, or an oxycarbonyl group, B represents a single bond or a divalent organic group having 1 to 20 carbon atoms, and R¹⁷ represents a monovalent organic group.

Specific examples of the alkyl group having 1 to 10 carbon atoms represented by R¹⁴ to R¹⁶ in the general formula (8) include a methyl group, an ethyl group, a propyl group, a butyl group, a pentyl group, a hexyl group, a heptyl group, an octyl group, a nonyl group, a decyl group, and the like. It is preferable that R¹⁴ and R¹⁵ represent a hydrogen atom, and R¹⁶ represents a hydrogen atom or a methyl group.

The monovalent organic group represented by R¹⁷ in the general formula (8) is preferably a monovalent organic group that includes a fluorine atom, more preferably a fluoroalkyl group having 1 to 20 carbon atoms, and still more preferably a fluoroalkyl group having 1 to 4 carbon atoms.

Specific examples of the fluoroalkyl group having 1 to 20 carbon atoms include a difluoromethyl group, a perfluoromethyl group, a 1,1-difluoroethyl group, a 2,2-difluoroethyl group, a 2,2,2-trifluoroethyl group, a perfluoroethyl group, a 1,1,2,2-tetrafluoropropyl group, a 1,1,2,2,3,3-hexafluoropropyl group, a perfluoroethylmethyl group, a 1-(trifluoromethyl)-1,2,2,2-tetrafluoroethyl group, a perfluoropropyl group, a 1,1,2,2-tetrafluorobutyl group, a 1,1,2,2,3,3-hexafluorobutyl group, a 1,1,2,2,3,3,4,4-octafluorobutyl group, a perfluorobutyl group, a 1,1-bis(trifluoro)methyl-2,2,2-trifluoroethyl group, a 2-(perfluoropropyl)ethyl group, a 1,1,2,2,3,3,4,4-octafluoropentyl group, a perfluoropentyl group, a 1,1,2,2,3,3,4,4,5,5-decafluoropentyl group, a 1,1-bis(trifluoromethyl)-2,2,3,3,3-pentafluoropropyl group, a perfluoropentyl group, a 2-(perfluorobutyl)ethyl group, a 1,1,2,2,3,3,4,4,5,5-decafluorohexyl group, a 1,1,2,2,3,3,4,4,5,5,6,6-dodecafluorohexyl group, a perfluoropentylmethyl group, a perfluorohexyl group, a 2-(perfluoropentyl)ethyl group, a 1,1,2,2,3,3,4,4,5,5,6,6-dodecafluoroheptyl group, a perfluorohexylmethyl group, a perfluoroheptyl group, a 2-(perfluorohexyl)ethyl group, a 1,1,2,2,3,3,4,4,5,5,6,6,7,7-tetradecafluorooctyl group, a perfluoroheptylmethyl group, a perfluorooctyl group, a 2-(perfluoroheptyl)ethyl group, a 1,1,2,2,3,3,4,4,5,5,6,6,7,7,8,8-hexadecafluorononyl group, a perfluorooctylmethyl group, a perfluorononyl group, a 2-(perfluorooctyl)ethyl group, a 1,1,2,2,3,3,4,4,5,5,6,6,7,7,8,8,9,9-octadecafluorodecyl group, a perfluorononylmethyl group, a perfluorodecyl group, and the like.

If the number of carbon atoms of the fluoroalkyl group is too large, the solubility of the resin in an alkaline solution may decrease. Therefore, a perfluoromethyl group, a perfluoroethyl group, and a perfluoropropyl group are preferable.

Specific examples of the divalent organic group having 1 to 20 carbon atoms represented by B in the general formula (8) include chain-like hydrocarbon groups such as a methylene group, an ethylene group, a propylene group (e.g., 1,3-propylene group and 1,2-propylene group), a tetramethylene group, a pentamethylene group, a hexamethylene group, a heptamethylene group, an octamethylene group, a nonamethylene group, a decamethylene group, an undecamethylene group, a dodecamethylene group, a tridecamethylene group, a tetradecamethylene group, a pentadecamethylene group, a hexadecamethylene group, a heptadecamethylene group, an octadecamethylene group, a nonadecamethylene group, an icosylene group, a 1-methyl-1,3-propylene group, a 2-methyl-1,3-propylene group, a 2-methyl-1,2-propylene group, a 1-methyl-1,4-butylene group, and a 2-methyl-1,4-butylene group; monocyclic hydrocarbon groups such as a cycloalkylene group having 3 to 10 carbon atoms, such as a cyclobutylene group (e.g., 1,3-cyclobutylene group), a cyclopentylene group (e.g., 1,3-cyclopentylene group), a cyclohexylene group (e.g., 1,4-cyclohexylene group), and a cyclooctylene group (e.g., 1,5-cyclooctylene group); crosslinked cyclic hydrocarbon groups such as a dicyclic to tetracyclic hydrocarbon group having 4 to 20 carbon atoms, such as a norbornylene group (e.g., 1,4-norbornylene group and 2,5-norbornylene group) and an admantylene group (e.g., 1,5-admantylene group and 2,6-admantylene group); and the like.

Preferable examples of the compound shown by the general formula (8) include 2-(((trifluoromethyl)sulfonyl)amino)ethyl-1-methacrylate, 2-(((trifluoromethyl)sulfonyl)amino)ethyl-1-acrylate, and the compounds shown by the following formulas (8-1) to (8-6).

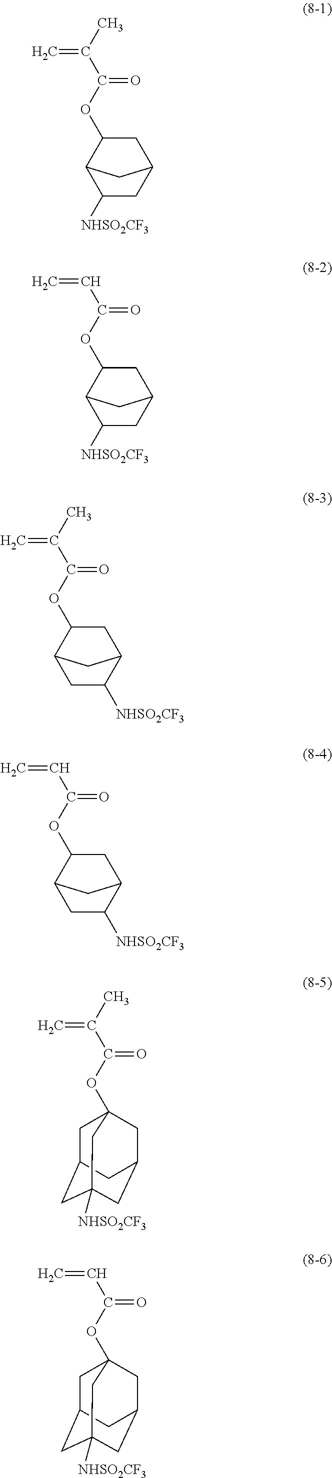

The compound shown by the general formula (8) is normally used in an amount of 1 to 50 mol %, preferably 2 to 30 mol %, and more preferably 2 to 20 mol %, based on the total amount of the monomer component.

### (2) Preparation Method

The hydroxyl group-containing resin may be prepared by polymerizing the monomer component in an appropriate solvent optionally in the presence of a chain transfer agent using a radical initiator (e.g., hydroperoxide, dialkyl peroxide, diacyl peroxide, or azo compound), for example. Examples of the solvent used for polymerization include alkanes such as n-pentane, n-hexane, n-heptane, n-octane, n-nonane, and n-decane; cycloalkanes such as cyclohexane, cycloheptane, cyclooctane, decalin, and norbornane; aromatic hydrocarbons such as benzene, toluene, xylene, ethylbenzene, and cumene; halogenated hydrocarbons such as chlorobutane, bromohexane, dichloroethane, hexamethylene dibromide, and chlorobenzene; saturated carboxylates such as ethyl acetate, n-butyl acetate, i-butyl acetate, methyl propionate, and propylene glycol monomethyl ether acetate; alkyllactones such as γ-butyrolactone; ethers such as tetrahydrofuran, dimethoxyethanes, and diethoxyethane; alkylketones such as 2-butanone, 2-heptanone, and methyl isobutyl ketone; cycloalkylketones such as cyclohexanone; alcohols such as 2-propanol, 1-butanol, 4-methyl-2-pentanol, and propylene glycol monomethyl ether; and the like. These solvents may be used either individually or in combination.

The reaction (polymerization) temperature is normally 40 to 120° C., and preferably 50 to 100° C. The reaction (polymerization) time is normally 1 to 48 hours, and preferably 1 to 24 hours.

It is preferable that the hydroxyl group-containing resin have high purity. Specifically, it is preferable that the hydroxyl group-containing resin have a low impurity (e.g., halogen and metal) content and a residual monomer/oligomer content equal to or lower than a given value (e.g., 0.1 mass % or less (determined by HPLC)). The process stability and the accuracy of the shape of the resist pattern can be improved using a resist pattern coating agent that includes a high-purity hydroxyl group-containing resin. The hydroxyl group-containing resin may be purified as follows, for example.

Specifically, impurities (e.g., metals) may be removed by causing metals included in the polymer solution to be adsorbed on a zeta-potential filter, or washing the polymer solution with an acidic aqueous solution (e.g., oxalic acid or sulfonic acid aqueous solution) to remove metals in a chelate state, for example. The residual monomer/oligomer content may be reduced to a value equal to or lower than a given value by liquid-liquid extraction that removes residual monomers and oligomers by washing with water or combining appropriate solvents, purification in a solution state (e.g., ultrafiltration) that extracts and removes only components having a molecular weight equal to or less than a given value, reprecipitation that removes residual monomers and the like by adding the polymer solution to a poor solvent dropwise so that the resin coagulates in the poor solvent, purification in a solid state that washes the resin collected by filtration with a poor solvent, or the like. These methods may be used in combination.

### (3) Property Value

The polystyrene-reduced weight average molecular weight (Mw) of the hydroxyl group-containing resin determined by gel permeation chromatography (GPC) is normally 1000 to 500,000, preferably 1000 to 50,000, and still more preferably 1000 to 20,000. If the Mw of the hydroxyl group-containing resin is more than 500,000, it may be difficult to remove the thermally cured resin using a developer. If the Mw of the hydroxyl group-containing resin is less than 1000, it may be difficult to form a uniform film.

### 2. Solvent

The solvent is preferably water or an alcohol solvent, and particularly preferably an alcohol solvent. Note that the term “alcohol solvent” refers to a solvent that includes an alcohol. The alcohol solvent preferably has a water content (i.e., the water content relative to the total amount of the solvent) of 10 mass % or less, and more preferably 3 mass % or less. If the water content of the alcohol solvent exceeds 10 mass %, the solubility of the hydroxyl group-containing resin may decrease. The alcohol solvent is particularly preferably an alcohol-containing non-aqueous solvent (i.e., an absolute alcohol solvent that does not substantially include water).

The solvent is preferably used in such an amount that the total content of the hydroxyl group-containing resin and the crosslinking agent in the resist pattern coating agent is 0.1 to 30 mass %, and more preferably 1 to 20 mass %. If the total content of the hydroxyl group-containing resin and the crosslinking agent is less than 0.1 mass %, the resulting film may break at the pattern edge due to a decrease in thickness. If the total content of the hydroxyl group-containing resin and the crosslinking agent exceeds 30 mass %, the viscosity of the resist pattern coating agent may increase to a large extent, so that it may be difficult to embed the resist pattern coating agent in a fine pattern.

### (1) Alcohol Solvent

An alcohol solvent that can sufficiently dissolve the hydroxyl group-containing resin and the crosslinking agent, and does not dissolve a first resist pattern formed using the first resist material may be used as the alcohol solvent. A monohydric alcohol having 1 to 8 carbon atoms is preferably used as the alcohol solvent. Specific examples of the monohydric alcohol having 1 to 8 carbon atoms include 1-propanol, isopropyl alcohol, 1-butanol, 2-butanol, t-butanol, 1-pentanol, 2-pentanol, 3-pentanol, 2-methyl-1-butanol, 3-methyl-1-butanol, 3-methyl-2-butanol, 1-hexanol, 2-hexanol, 3-hexanol, 2-methyl-1-pentanol, 2-methyl-2-pentanol, 2-methyl-3-pentanol, 3-methyl-1-pentanol, 3-methyl-2-pentanol, 3-methyl-3-pentanol, 4-methyl-1-pentanol, 4-methyl-2-pentanol, 1-heptanol, 2-heptanol, 2-methyl-2-heptanol, 2-methyl-3-heptanol, and the like. Among these, 1-butanol, 2-butanol, and 4-methyl-2-pentanol are preferable. These alcohol solvents may be used either individually or in combination.

### (2) Additional Solvent

The solvent may include an additional solvent other than the alcohol solvent in order to adjust the applicability when applying the resist pattern coating agent to the first resist pattern. The additional solvent may be a solvent that allows uniform application of the resist pattern coating agent without dissolving the first resist pattern.

Specific examples of the additional solvent include cyclic ethers such as tetrahydrofuran and dioxane; alkyl ethers of polyhydric alcohols such as ethylene glycol monomethyl ether, ethylene glycol monoethyl ether, ethylene glycol dimethyl ether, ethylene glycol diethyl ether, diethylene glycol monomethyl ether, diethylene glycol monoethyl ether, diethylene glycol dimethyl ether, diethylene glycol diethyl ether, diethylene glycol ethyl methyl ether, propylene glycol monomethyl ether, and propylene glycol monoethyl ether; alkyl ether acetates of polyhydric alcohols such as ethylene glycol ethyl ether acetate, diethylene glycol ethyl ether acetate, propylene glycol ethyl ether acetate, and propylene glycol monomethyl ether acetate; aromatic hydrocarbons such as toluene and xylene; ketones such as acetone, methyl ethyl ketone, methyl isobutyl ketone, cyclohexanone, 4-hydroxy-4-methyl-2-pentanone, and diacetone alcohol; esters such as ethyl acetate, butyl acetate, ethyl 2-hydroxypropionate, ethyl 2-hydroxy-2-methylpropionate, ethoxyethyl acetate, ethyl hydroxyacetate, methyl 2-hydroxy-3-methylbutanoate, methyl 3-methoxypropionate, ethyl 3-methoxypropionate, ethyl 3-ethoxypropionate, methyl 3-ethoxypropionate, ethyl acetate, and butyl acetate; water; and the like. Among these, cyclic ethers, alkyl ethers of polyhydric alcohols, alkyl ether acetates of polyhydric alcohols, ketones, esters, and water are preferable.

The additional solvent is normally used in an amount of 30 mass % or less, and preferably 20 mass % or less, based on the total amount of the solvent. If the amount of the additional solvent is more than 30 mass %, the first resist pattern may be dissolved so that intermixing with the resist pattern coating agent may occur (i.e., the first resist pattern may be buried). When the additional solvent is water, water is preferably used in an amount of 10 mass % or less.

### 3. Crosslinking Agent

The crosslinking agent reacts with a resist resin (described later) the hydroxyl group-containing resin, or the like and/or another crosslinking agent due to an acid or heat, so that the resist pattern coating agent is cured. The crosslinking agent is at least two compounds selected from the group consisting of the crosslinking agent (1) to (3), or a compound that includes only the crosslinking agent (1). The crosslinking agent is preferably used in an amount of 1 to 100 parts by mass, and more preferably 1 to 80 parts by mass, based on 100 parts by mass of the hydroxyl group-containing resin. If the amount of the crosslinking agent is less than 1 part by mass, the curability of the resist pattern coating agent may decrease. If the amount of the crosslinking agent exceeds 100 parts by mass, it may be difficult to control the pattern size.

### (1) Crosslinking Agent (1)

The crosslinking agent (1) is preferably shown by the following general formula (1-1) or (1-2).

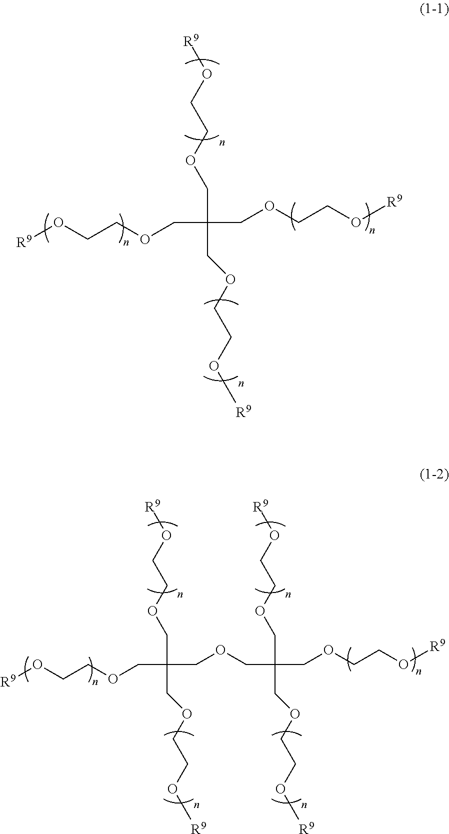

wherein n are individually an integer from 0 to 10, and R⁹ individually represent a hydrogen atom or a group shown by the following general formula (5), provided that at least two of R⁹ represent a group shown by the general formula (5),

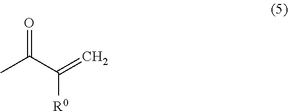

wherein R⁰ represents a hydrogen atom or a methyl group.

Specific examples of the crosslinking agent (1) include pentaerythritol triacylate, pentaerythritol tetraacrylate, dipentaerythritol hexaacrylate, and the like. Examples of commercially available products that may be used as the crosslinking agent (1) include KAYARAD T-1420 (T), KAYARAD RP-1040, KAYARAD DPHA, KAYARAD DPEA-12, KAYARAD DPHA-2C, KAYARAD D-310, KAYARAD D-330 (manufactured by Nippon Kayaku Co., Ltd.), NK Ester ATM-2.4E, NK Ester ATM-4E, NK Ester ATM-35E, NK Ester ATM-4P (manufactured by Shin-Nakamura Chemical Co., Ltd.), M-309, M-310, M-321, M-350, M-360, M-370, M-313, M-315, M-327, M-306, M-305, M-451, M-450, M-408, M-2035, M-208, M-211B, M-215, M-220, M-225, M-270, M-240 (manufactured by Toagosei Co., Ltd.), and the like. These crosslinking agents (1) may be used either individually or in combination.

The crosslinking agent (1) is preferably used in an amount of 1 to 100 parts by mass, and more preferably 5 to 70 parts by mass, based on 100 parts by mass of the hydroxyl group-containing resin. If the amount of the crosslinking agent (1) is less than 1 part by mass, the resist pattern coating agent may not be sufficiently cured, so that the resist pattern may not shrink. If the amount of the crosslinking agent (1) exceeds 100 parts by mass, the resist pattern coating agent may be cured to a large extent, so that the resist pattern may be buried.

### (2) Crosslinking Agent (2)

The crosslinking agent (2) is preferably shown by the following general formula (2-1).

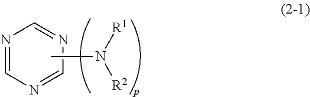

wherein R¹ and R² represent a hydrogen atom or a group shown by the following general formula (3), provided that at least one of R¹ and R² represents a group shown by the general formula (3), and p is an integer from 1 to 3,

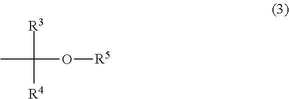

wherein R³ and R⁴ represent a hydrogen atom, an alkyl group having 1 to 6 carbon atoms, or an alkoxyalkyl group having 1 to 6 carbon atoms, or bond to form a ring having 2 to 10 carbon atoms, and R⁵ represents a hydrogen atom or an alkyl group having 1 to 6 carbon atoms.

Examples of the crosslinking agent (2) include compounds including a functional group such as an imino group, a methylol group, or a methoxymethyl group in the molecule. Specific examples of these compounds include nitrogen-containing compounds obtained by alkyl-etherification of all or some of the active methylol groups of (poly)methylolated melamine, (poly)methylolated glycoluril, (poly)methylolated benzoquanamine, (poly)methylolated urea, or the like. Specific examples of the alkyl group include a methyl group, an ethyl group, a butyl group, and a combination thereof. The nitrogen-containing compound may include an oligomer component that is partially self-condensed. Specific examples of the nitrogen-containing compound include hexamethoxymethylated melamine, hexabutoxymethylated melamine, tetramethoxymethylated glycoluril, tetrabutoxymethylated glycoluril, and the like.

Specific examples of the crosslinking agent (2) include Cymel 300, Cymel 301, Cymel 303, Cymel 350, Cymel 232, Cymel 235, Cymel 236, Cymel 238, Cymel 266, Cymel 267, Cymel 285, Cymel 1123, Cymel 1123-10, Cymel 1170, Cymel 370, Cymel 771, Cymel 272, Cymel 1172, Cymel 325, Cymel 327, Cymel 703, Cymel 712, Cymel 254, Cymel 253, Cymel 212, Cymel 1128, Cymel 701, Cymel 202, Cymel 207(manufactured by Nihon Cytec Industries, Inc.), Nikalac MW-30M, Nikalac MW-30, Nikalac MW-22, Nikalac MW-24X, Nikalac MS-21, Nikalac MS-11, Nikalac MS-001, Nikalac MX-002, Nikalac MX-730, Nikalac MX-750, Nikalac MX-708, Nikalac MX-706, Nikalac MX-042, Nikalac MX-035, Nikalac MX-45, Nikalac MX-410, Nikalac MX-302, Nikalac MX-202, Nikalac SM-651, Nikalac SM-652, Nikalac SM-653, Nikalac SM-551, Nikalac SM-451, Nikalac SB-401, Nikalac SB-355, Nikalac SB-303, Nikalac SB-301, Nikalac SB-255, Nikalac SB-203, Nikalac SB-201, Nikalac BX-4000, Nikalac BX-37, Nikalac BX-55H, Nikalac BL-60 (manufactured by Sanwa Chemical Co., Ltd.), and the like. Among these, Cymel 325,Cymel 327, Cymel 703, Cymel 712, Cymel 254, Cymel 253, Cymel 212, Cymel 1128, Cymel 701, Cymel 202, and Cymel 207 (corresponding to the compound shown by the general formula (2) wherein R¹ or R² represents a hydrogen atom (i.e., imino group)) are preferable. These crosslinking agents (2) may be used either individually or in combination.

The crosslinking agent (2) is preferably used in an amount of 1 to 80 parts by mass, and more preferably 1 to 50 parts by mass, based on 100 parts by mass of the hydroxyl group-containing resin. If the amount of the crosslinking agent (2) is less than 1 part by mass, the resist pattern coating agent may not be sufficiently cured, so that the resist pattern may not shrink. If the amount of the crosslinking agent (2) exceeds 80 parts by mass, the resist pattern coating agent may be cured to a large extent, so that the resist pattern may be buried.

### (3) Crosslinking Agent (3)

The crosslinking agent (3) is preferably shown by the following general formula (4-1).

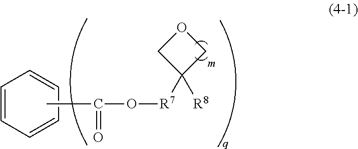

wherein R⁷ represents a single bond, a methylene group, a linear or branched alkylene group having 2 to 10 carbon atoms, or a divalent cyclic hydrocarbon group having 3 to 20 carbon atoms, R⁸ represents a linear or branched alkyl group having 1 to 10 carbon atoms or a monovalent cyclic hydrocarbon group having 3 to 20 carbon atoms, m is 0 or 1, and q is an integer from 1 to 3.

Specific examples of the crosslinking agent (3) include epoxycyclohexyl group-containing compounds such as 3,4-epoxycyclohexylmethyl-3′,4′-epoxycyclohexane carboxylate, 2-(3,4-epoxycyclohexyl-5,5-spiro-3,4-epoxy)cyclohexane-m-dioxane, bis(3,4-epoxycyclohexylmethyl)adipate, bis(3,4-epoxy-6-methylcyclohexylmethyl)adipate, 3,4-epoxy-6-methylcyclohexyl-3′,4′-epoxy-6′-methylcyclohexane carboxylate, methylenebis(3,4-epoxycyclohexane), ethylene glycol di(3,4-epoxycyclohexylmethyl)ether, ethylenebis(3,4-epoxycyclohexane carboxylate), epsilon-caprolactone-modified 3,4-epoxycyclohexylmethyl-3′,4′-epoxycyclohexane carboxylate, trimethylcaprolactone-modified 3,4-epoxycyclohexylmethyl-3′,4′-epoxycyclohexane carboxylate, and β-methyl-delta-valerolactone-modified 3,4-epoxycyclohexylmethyl-3′,4′-epoxycyclohexane carboxylate; diglycidyl ethers such as bisphenol A diglycidyl ether, bisphenol F diglycidyl ether, bisphenol S diglycidyl ether, brominated bisphenol A diglycidyl ether, brominated bisphenol F diglycidyl ether, brominated bisphenol S diglycidyl ether, hydrogenated bisphenol A diglycidyl ether, hydrogenated bisphenol F diglycidyl ether, hydrogenated bisphenol S diglycidyl ether, 1,4-butanediol diglycidyl ether, 1,6-hexanediol diglycidyl ether, glycerol triglycidyl ether, trimethylolpropane triglycidyl ether, polyethylene glycol diglycidyl ether, and polypropylene glycol diglycidyl ether; polyglycidyl ethers of polyether polyols obtained by adding at least one alkylene oxide to an aliphatic polyhydric alcohol (e.g., ethylene glycol, propylene glycol, or glycerol); diglycidyl esters of aliphatic long-chain dibasic acids; monoglycidyl ethers of aliphatic higher alcohols; monoglycidyl ethers of phenol, cresol, butylphenol, or a polyether alcohol obtained by addition of an alkylene oxide thereto; glycidyl esters of higher fatty acids; 3,7-bis(3-oxetanyl)-5-oxanonane, 3,3′-(1,3-(2-methylenyl)propanediylbis(oxymethylene))bis-(3-ethyloxetane), 1,4-bis[(3-ethyl-3-oxetanylmethoxy)methyl]benzene, 1,2-bis[(3-ethyl-3-oxetanylmethoxy)methyl]ethane, 1,3-bis[(3-ethyl-3-oxetanylmethoxy)methy]propane, ethylene glycol bis(3-ethyl-3-oxetanylmethyl)ether, dicyclopentenyl bis(3-ethyl-3-oxetanylmethyl)ether, triethylene glycol bis(3-ethyl-3-oxetanylmethyl)ether, tetraethylene glycol bis(3-ethyl-3-oxetanylmethyl)ether, tricyclodecanediyldimethylene(3-ethyl-3-oxetanylmethyl)ether, trimethylolpropane tris(3-ethyl-3-oxetanylmethyl)ether, 1,4-bis(3-ethyl-3-oxetanylmethoxy)butane, 1,6-bis(3-ethyl-3-oxetanylmethoxy)hexane, pentaerythritol tris(3-ethyl-3-oxetanylmethyl)ether, pentaerythritol tetrakis(3-ethyl-3-oxetanylmethyl)ether, polyethylene glycol bis(3-ethyl-3-oxetanylmethyl)ether, dipentaerythritol hexakis(3-ethyl-3-oxetanylmethyl)ether, dipentaerythritol pentakis(3-ethyl-3-oxetanylmethyl)ether, dipentaerythritol tetrakis(3-ethyl-3-oxetanylmethyl)ether, caprolactone-modified dipentaerythritol hexakis(3-ethyl-3-oxetanylmethyl)ether, caprolactone-modified dipentaerythritol pentakis(3-ethyl-3-oxetanylmethyl)ether, ditrimethylolpropane tetrakis(3-ethyl-3-oxetanylmethyl)ether, ethylene oxide (EO)-modified bisphenol A bis(3-ethyl-3-oxetanylmethyl)ether, propylene oxide (PO)-modified bisphenol A bis(3-ethyl-3-oxetanylmethyl)ether, EO-modified hydrogenated bisphenol A bis(3-ethyl-3-oxetanylmethyl)ether, PO-modified hydrogenated bisphenol A bis(3-ethyl-3-oxetanylmethyl)ether, and EO-modified bisphenol F (3-ethyl-3-oxetanylmethyl)ether. Specific examples of commercially available compounds that may be used as the crosslinking agent (3) include oxetane compounds including one or more oxetane rings in the molecule, such as Aron Oxetane OXT-101, Aron Oxetane OXT-121, Aron Oxetane OXT-221 (manufactured by Toagosei Co., Ltd.), OXMA, OXTP, OXBP, and OXIPA (manufactured by Ube Industries, Ltd.).

Among these, 1,6-hexanediol diglycidyl ether, dipentaerythritol hexakis(3-ethyl-3-oxetanylmethyl)ether, and OXIPA are preferable as the crosslinking agent (3). These crosslinking agents (3) may be used either individually or in combination.

The crosslinking agent (3) is preferably used in an amount of 1 to 80 parts by mass, and more preferably 5 to 50 parts by mass, based on 100 parts by mass of the hydroxyl group-containing resin. If the amount of the crosslinking agent (3) is less than 1 part by mass, the resist pattern coating agent may not be sufficiently cured, so that the resist pattern may not shrink. If the amount of the crosslinking agent (3) exceeds 80 parts by mass, the resist pattern coating agent may be cured to a large extent, so that the resist pattern may be buried.

### 4. Surfactant

A surfactant may be added to the resist pattern coating agent according to one embodiment of the invention in order to improve the applicability, the defoamability, the leveling properties, and the like of the resist pattern coating agent. Specific examples of the surfactant that may be added to the resist pattern coating agent include fluorine-containing surfactants such as BM-1000, BM-1100 (manufactured by BM Chemie), Megafac F142D, F172, F173, F183 (manufactured by DIC Corporation), Fluorad FC-135, FC-170C, FC-430, FC-431 (manufactured by Sumitomo 3M, Ltd.), Surflon S-112, S-113, S-131, S-141, S-145 (manufactured by Asahi Glass Co., Ltd.), SH-28PA, SH-190, SH-193, SZ-6032, SF-8428 (manufactured by Dow Corning Toray Silicone Co., Ltd.), and the like. The surfactant is preferably used in an amount of 5 parts by mass or less based on 100 parts by mass of the hydroxyl group-containing resin.

### II. Resist Pattern-Forming Method

A resist pattern-forming method according to one embodiment of the invention includes (1) forming a first resist pattern on a substrate using a first positive-tone radiation-sensitive resin composition, applying the resist pattern coating agent according to one embodiment of the invention to the first resist pattern, baking or UV-curing the resist pattern coating agent, and washing the baked or UV-cured resist pattern coating agent to form an insolubilized resist pattern that is insoluble in a developer and a second positive-tone radiation-sensitive resin composition (hereinafter may be referred to as “step (1)”), (2) forming a second resist layer on the insolubilized resist pattern using the second positive-tone radiation-sensitive resin composition, and selectively exposing the second resist layer through a mask (hereinafter may be referred to as “step (2)”), and (3) developing the second resist layer to form a second resist pattern (hereinafter may be referred to as “step (3)”).

### 1. Step (1)

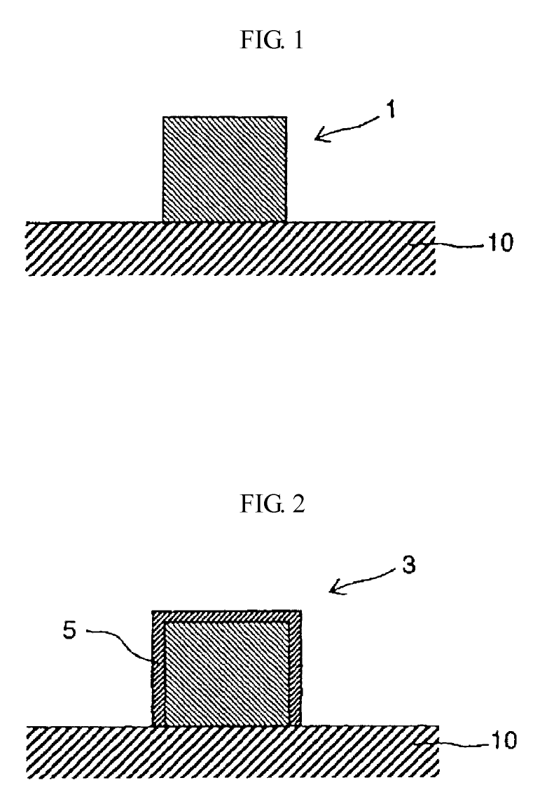

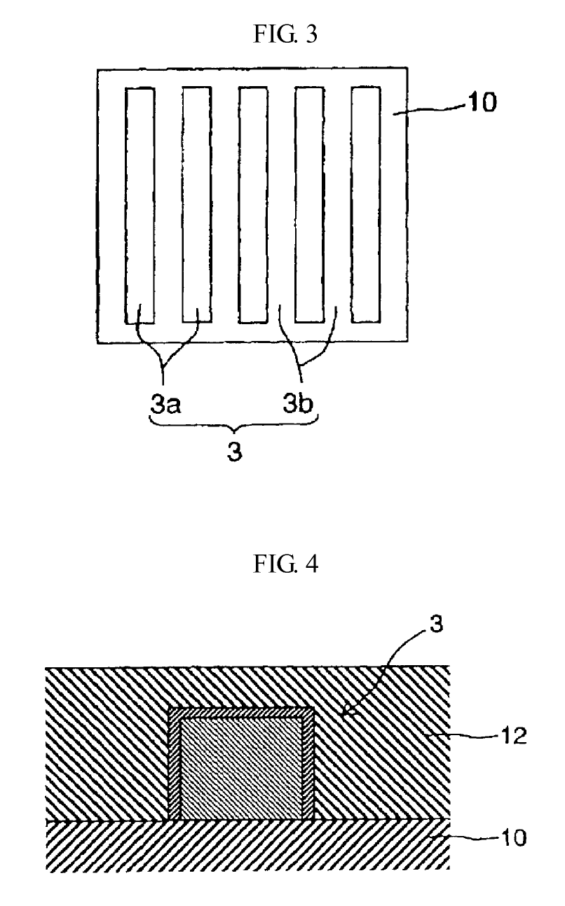

FIG. 1 is a cross-sectional view showing an example of the step (1) of the resist pattern-forming method according to one embodiment of the invention (i.e., a state in which the first resist pattern is formed on the substrate). FIG. 2 is a cross-sectional view showing an example of the step (1) of the resist pattern-forming method according to one embodiment of the invention (i.e., a state in which the insolubilized resist pattern is formed). FIG. 3 is a schematic view showing an example of the step (1) of the resist pattern-forming method according to one embodiment of the invention (i.e., a state in which the insolubilized resist pattern is formed). In the step (1), the resist pattern coating agent according to one embodiment of the invention is applied to a first resist pattern 1 formed on a substrate 10 using a first resist material (described later), baked or UV-cured, and then washed to form an insolubilized resist pattern 3 that is insoluble in a developer and a second resist material (described later) (see FIGS. 2 and 3).

### (1) Formation of First Resist Pattern

The first resist pattern may be formed by an arbitrary method. For example, the first resist material is applied to the substrate (e.g., a silicon wafer or a wafer coated with SiN, an organic antireflective film, or the like) by an appropriate application method (e.g., spin coating, cast coating, or roll coating) to form a first resist layer. After applying the first resist material, the resulting film (first resist material) may optionally be prebaked (PB) to vaporize the solvent from the first resist layer. The PB temperature is appropriately selected depending on the composition of the first resist material, but is normally 30 to 200° C., and preferably 50 to 150° C.

In order to bring out the potential of the first resist material to a maximum extent, an organic or inorganic antireflective film is preferably formed on the substrate 10, as disclosed in Japanese Examined Patent Publication (KOKOKU) No. 6-12452, for example. A protective film may preferably be formed on the first resist layer in order to prevent an adverse effect of basic impurities and the like present in the environmental atmosphere, as disclosed in Japanese Patent Application Publication (KOKAI) No. 5-188598, for example. It is also preferable to form both the antireflective film and the protective film.

The first resist layer thus formed is exposed by applying radiation to the desired area of the first resist layer through a mask having a given pattern to form an alkali-developable area (i.e., an area that has become alkali-soluble due to exposure). Radiation used for exposure is appropriately selected from visible rays, ultraviolet rays, deep ultraviolet rays, X-rays, electron beams, charged particle rays, and the like depending on the type of acid generator included in the first resist material. It is preferable to use deep ultraviolet rays such as ArF excimer laser light (wavelength: 193 nm) and KrF excimer laser light (wavelength: 248 nm). It is particularly preferable to use ArF excimer laser light (wavelength: 193 nm). The exposure conditions (e.g., dose) are appropriately selected depending on the composition of the first resist material, the type of additive, and the like. It is preferable to perform post-exposure bake (PEB). An acid-dissociable group included in the resin component of the first resist material smoothly dissociates due to PEB. The PEB temperature is appropriately selected depending on the composition of the first resist material, but is normally 30 to 200° C., and preferably 50 to 170° C.

The exposed first resist layer is developed so that the alkali-developable area is dissolved. The positive-tone first resist pattern 1 shown in FIG. 1 that has a given line width (i.e., has a given space area) is thus formed on the substrate 10. A developer that may be used for development is preferably an alkaline aqueous solution prepared by dissolving at least one alkaline compound (e.g., sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, ethyldimethylamine, triethanolamine, tetramethylammonium hydroxide, pyrrole, piperidine, choline, 1,8-diazabicyclo-[5.4.0]-7-undecene, or 1,5-diazabicyclo-[4.3.0]-5-nonene) in water. The concentration of the alkaline aqueous solution is normally 10 mass % or less. If the concentration of the alkaline aqueous solution exceeds 10 mass %, the unexposed area may be easily dissolved in the developer. After development using the alkaline aqueous solution, the resist pattern is normally washed with water, and dried.

An organic solvent may be added to the alkaline aqueous solution (developer). Examples of the organic solvent that may be added to the alkaline aqueous solution include ketones such as acetone, methyl ethyl ketone, methyl i-butyl ketone, cyclopentanone, cyclohexanone, 3-methylcyclopentanone, and 2,6-dimethylcyclohexanone; alcohols such as methanol, ethanol, n-propyl alcohol, i-propyl alcohol, n-butyl alcohol, t-butyl alcohol, cyclopentanol, cyclohexanol, 1,4-hexanediol, and 1,4-hexanedimethylol; ethers such as tetrahydrofuran and dioxane; esters such as ethyl acetate, n-butyl acetate, and i-amyl acetate; aromatic hydrocarbons such as toluene and xylene; phenol, acetonylacetone, dimethylformamide, and the like. These organic solvents may be used either individually or in combination.

The organic solvent is preferably added in an amount of 100 parts by volume or less based on 100 parts by volume of the alkaline aqueous solution. If the amount of the organic solvent exceeds 100 parts by volume based on 100 parts by volume of the alkaline aqueous solution, the developability may decrease, so that the exposed area may remain undeveloped. An appropriate amount of a surfactant or the like may be added to the developer.

### (2) Insolubilizing Step

The resist pattern coating agent according to one embodiment of the invention is applied to the first resist pattern by an appropriate application method (e.g., spin coating, cast coating, or roll coating). The resist pattern coating agent is applied to cover the surface of the first resist pattern.

The resist pattern coating agent is then baked or UV-cured. This causes the first resist pattern to react with the applied resist pattern coating agent. The baking temperature is appropriately selected depending on the composition of the resist pattern coating agent, but is normally 30 to 200° C., and preferably 50 to 170° C. The resist pattern coating agent may be UV-cured using an Ar₂ lamp, a KrCl lamp, a Kr₂ lamp, an XeCl lamp, an Xe₂ lamp (manufactured by Ushio, Inc.), or the like.

After appropriately cooling the resist pattern coating agent, the resist pattern coating agent is developed in the same manner as in the case of forming the first resist pattern to form an insolubilized resist pattern 3 (i.e., a pattern in which the surface of the first resist pattern 1 is covered with an insoluble film 5) that is a line-and-space pattern including first line areas 3a and first space areas 3b (see FIGS. 2 and 3), for example. The insolubilized resist pattern 3 (first line areas 3a) is insoluble or scarcely soluble in a developer and the second resist material. After development, the insolubilized resist pattern 3 may optionally be repeatedly cured by PEB or UV-curing.

The pattern shape of the insolubilized first resist pattern 1 (insolubilized resist pattern 3) does not change even when applying the second resist material to the insolubilized resist pattern 3, and exposing and developing the resulting second resist layer in the steps (2) and (3). Note that the line width of the pattern may change to some extent depending on the thickness of the applied resist pattern coating agent, and the like.

### 2. Step (2)

FIG. 4 is a cross-sectional view showing an example of the step (2) of the resist pattern-forming method according to one embodiment of the invention (i.e., a state in which the second resist layer is formed on the insolubilized resist pattern). In the step (2), the second resist material is applied to the insolubilized resist pattern 3 formed on the substrate 10 by an appropriate application method (e.g., spin coating, cast coating, or roll coating) to form a second resist layer 12 (see FIG. 4), for example. The applied second resist material may optionally be prebaked (PB). The second resist layer 12 is selectively exposed through a mask optionally together with the first space areas 3b of the insolubilized resist pattern 3. The second resist layer 12 may optionally be subjected to post-exposure bake (PEB).

### 3. Step (3)

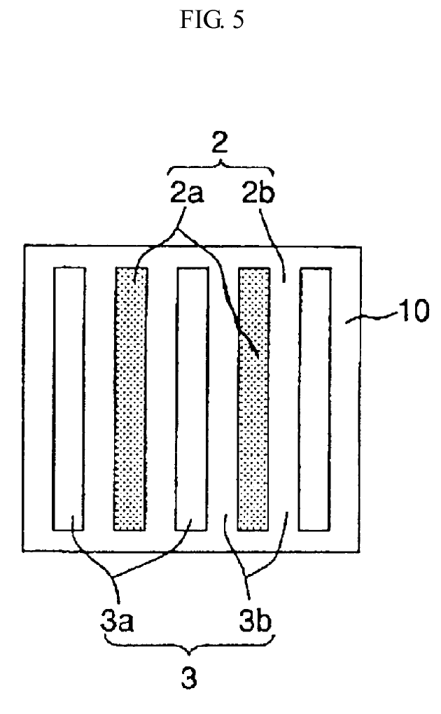

FIGS. 5 to 7 are schematic views showing an example of the step (3) of the resist pattern-forming method according to one embodiment of the invention (i.e., a state in which the second resist pattern is formed). FIG. 8 is a side view showing an example of the step (3) of the resist pattern-forming method according to one embodiment of the invention (i.e., a state in which the second resist pattern is formed). In the step (3), the exposed second resist layer 12 is developed to form a positive-tone second resist pattern 2 (see FIG. 5), for example. The insolubilizing step, the step (2), and the step (3) may be repeatedly performed after the step (3). A resist pattern in which the insolubilized resist pattern 3 and the second resist pattern 2 are sequentially formed on the substrate 10 can be formed by the above steps. A semiconductor device may be produced by utilizing the resist pattern thus formed. The second resist layer may be developed in the same manner as in the step (1).

Various resist patterns having a specific pattern arrangement can be formed by appropriately selecting the pattern of the mask used during exposure in the step (2). As shown in FIG. 5, when forming the insolubilized resist pattern 3 including the first line areas 3a and the first space areas 3b on the substrate 10, the second resist pattern 2 including second line areas 2a and second space areas 2b can be formed so that the second line areas 2a are formed in the first space areas 3b to be parallel to the first line areas 3a by selecting the pattern of the mask used during exposure in the step (2), for example.

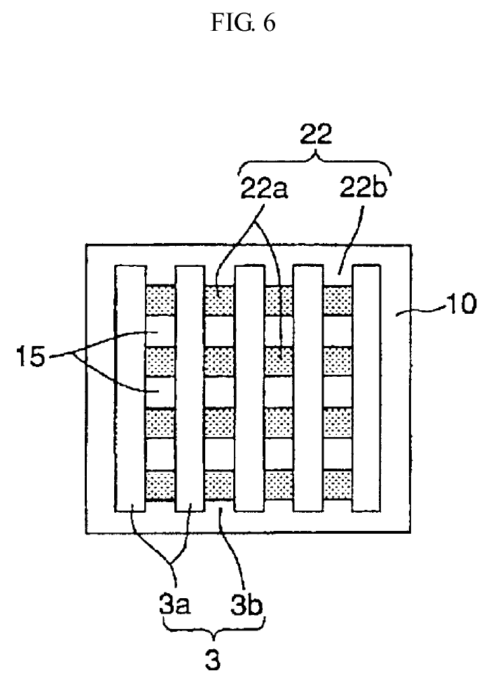

As shown in FIG. 6, a resist pattern (contact hole pattern) that includes contact holes 15 defined by the first line areas 3a and the second line areas 22a can be formed by forming the second line areas 22a of the second resist pattern 22 including the second line areas 22a and the second space areas 22b in a grid shape in the first space areas 3b of the insolubilized resist pattern 3 including the third line areas 3a and the third space areas 3b, for example.

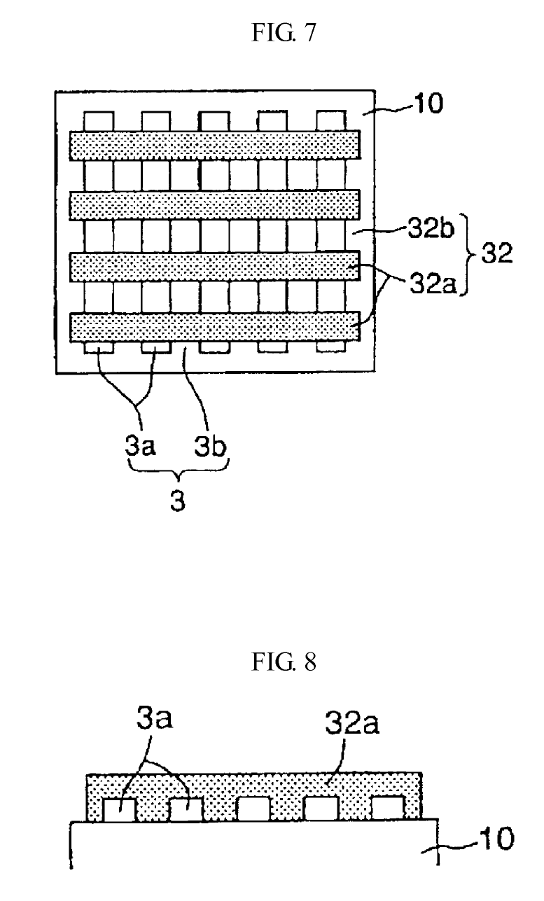

As shown in FIGS. 7 and 8, second line areas 32a of a second resist pattern 32 including the second line areas 32a and second space areas 32b may be formed over the first line areas 3a of the insolubilized resist pattern 3 including the first line areas 3a and the first space areas 3b so that the second line areas 32a intersect the first line areas 3a, for example.

### III. Resist Material

The first resist material and the second resist material used in the resist pattern-forming method according to one embodiment of the invention are positive-tone resist materials that are designed so that an acid-dissociable group included therein dissociates due to an acid generated from an acid generator upon exposure, and the exposed area of the resist is dissolved and removed in an alkaline developer due to an increase in solubility in an alkaline developer to obtain a positive-tone resist pattern. The first resist material and the second resist material may be either the same or different. The first resist material and the second resist material are hereinafter collectively referred to as “resist material”.

The resist material includes a resin that includes an acid-dissociable group-containing repeating unit (hereinafter referred to as “resist resin”), an acid generator, and a solvent.

### 1. Resist Resin

### (1) Component

The resist resin includes an acid-dissociable group-containing repeating unit, and preferably includes a repeating unit shown by the following general formula (9).

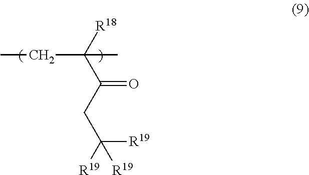

wherein R¹⁸ represents a hydrogen atom or a methyl group, and R¹⁹ individually represent a monovalent alicyclic hydrocarbon group having 4 to 20 carbon atoms, a derivative thereof, or a linear or branched alkyl group having 1 to 4 carbon atoms, provided that at least one of R¹⁹ represents a monovalent alicyclic hydrocarbon group having 4 to 20 carbon atoms or a derivative thereof, or two of R¹⁹ bond to form a divalent alicyclic hydrocarbon group having 4 to 20 carbon atoms, or a derivative thereof, together with the carbon atom that is bonded thereto, and the remaining R¹⁹ represents a linear or branched alkyl group having 1 to 4 carbon atoms, a monovalent alicyclic hydrocarbon group having 4 to 20 carbon atoms, or a derivative thereof.

Specific examples of the monovalent alicyclic hydrocarbon group having 4 to 20 carbon atoms represented by R¹⁹ in the general formula (9) and the divalent alicyclic hydrocarbon group having 4 to 20 carbon atoms formed by two of R¹⁹ include a group that includes an alicyclic ring derived from a cycloalkane such as norbornane, tricyclodecane, tetracyclododecane, adamantane, cyclobutane, cyclopentane, cyclohexane, cycloheptane, or cyclooctane; a group obtained by substituting the group that includes an alicyclic ring with at least one linear, branched, or cyclic alkyl group having 1 to 4 carbon atoms, such as a methyl group, an ethyl group, an n-propyl group, an i-propyl group, an n-butyl group, a 2-methylpropyl group, a 1-methylpropyl group, or a t-butyl group; and the like. Among these, a group that includes an alicyclic ring derived from norbornane, tricyclodecane, tetracyclododecane, adamantane, cyclopentane, or cyclohexane, and a group obtained by substituting the above group with an alkyl group are preferable.

Specific examples of the derivative of the monovalent alicyclic hydrocarbon group having 4 to 20 carbon atoms represented by R¹⁹ in the general formula (9) include groups including at least one substituent selected from a hydroxyl group; a carboxyl group; an oxo group (═O); a hydroxyalkyl group having 1 to 4 carbon atoms such as a hydroxymethyl group, a 1-hydroxyethyl group, a 2-hydroxyethyl group, a 1-hydroxypropyl group, a 2-hydroxypropyl group, a 3-hydroxypropyl group, a 1-hydroxybutyl group, a 2-hydroxybutyl group, a 3-hydroxybutyl group, and a 4-hydroxybutyl group; an alkoxy group having 1 to 4 carbon atoms such as a methoxy group, an ethoxy group, an n-propoxy group, an i-propoxy group, an n-butoxy group, a 2-methylpropoxy group, a 1-methylpropoxy group, and a t-butoxy group; a cyano group; and a cyanoalkyl group having 2 to 5 carbon atoms such as a cyanomethyl group, a 2-cyanoethyl group, a 3-cyanopropyl group, and a 4-cyanobutyl group; and the like. Among these, a hydroxyl group, a carboxyl group, a hydroxymethyl group, a cyano group, and a cyanomethyl group are preferable as the substituent.

Specific examples of the linear or branched alkyl group having 1 to 4 carbon atoms represented by R¹⁹ in the general formula (9) include a methyl group, an ethyl group, an n-propyl group, an i-propyl group, an n-butyl group, a 2-methylpropyl group, a 1-methylpropyl group, a t-butyl group, and the like. Among these, a methyl group and an ethyl group are preferable.

Specific examples of the group shown by “—C(R¹⁹)₃” in the general formula (9) include groups shown by the following general formulas (9a) to (9f).

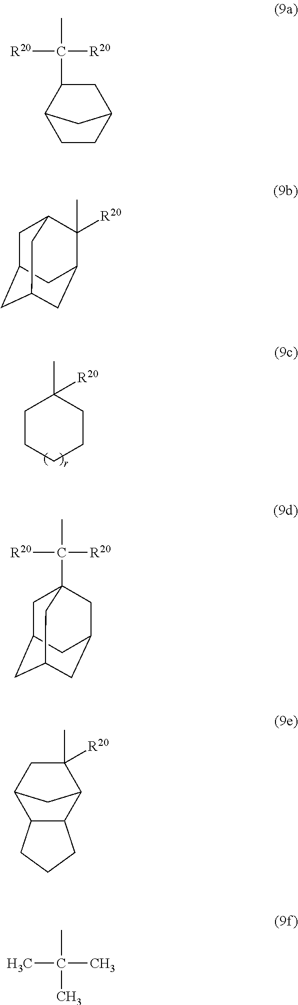

wherein R²⁰ individually represent a linear or branched alkyl group having 1 to 4 carbon atoms, and r is 0 or 1.

Specific examples of the linear or branched alkyl group having 1 to 4 carbon atoms represented by R²⁰ in the general formula (9a) to (9e) include a methyl group, an ethyl group, an n-propyl group, an i-propyl group, an n-butyl group, a 2-methylpropyl group, a 1-methylpropyl group, a t-butyl group, and the like. Among these, a methyl group and an ethyl group are preferable.

The group shown by “—COOC(R¹⁹)₃” in the general formula (9) dissociates due to an acid to form a carboxyl group, and serves as an alkali-soluble moiety. The term “alkali-soluble moiety” refers to a (alkali-soluble) group that becomes an anion due to alkali. The term “acid-dissociable group” refers to a group in which the alkali-soluble moiety is protected by a protecting group, and which is not alkali-soluble until the protecting group dissociates due to an acid.

The resist resin is insoluble or scarcely soluble in alkali, but becomes alkali-soluble due to an acid. The expression “insoluble or scarcely soluble in alkali” means that a film formed only of a resin that includes a repeating unit shown by the general formula (9) has a thickness equal to or more than 50% of the initial thickness when developed under development conditions employed when forming a resist pattern using a resist layer formed of a resist material including a resin that includes a repeating unit shown by the general formula (9). The expression “alkali-soluble” means that 50% or more of the initial thickness of the film is lost when developed under the above development conditions.

### (2) Preparation Method

The resist resin may be prepared by polymerizing a monomer component that includes a polymerizable unsaturated monomer corresponding to the desired repeating unit in an appropriate solvent optionally in the presence of a chain transfer agent using a radical initiator (e.g., hydroperoxide, dialkyl peroxide, diacyl peroxide, or azo compound).

Examples of the solvent used for polymerization include alkanes such as n-pentane, n-hexane, n-heptane, n-octane, n-nonane, and n-decane; cycloalkanes such as cyclohexane, cycloheptane, cyclooctane, decalin, and norbornane; aromatic hydrocarbons such as benzene, toluene, xylene, ethylbenzene, and cumene; halogenated hydrocarbons such as chlorobutanes, bromohexanes, dichloroethanes, hexamethylene dibromide, and chlorobenzene; saturated carboxylic acid esters such as ethyl acetate, n-butyl acetate, i-butyl acetate, and methyl propionate; ethers such as tetrahydrofuran, dimethoxyethanes, and diethoxyethanes; alcohols such as methanol, ethanol, 1-propanol, 2-propanol, 1-butanol, 2-butanol, isobutanol, 1-pentanol, 3-pentanol, 4-methyl-2-pentanol, o-chlorophenol, and 2-(1-methylpropyl)phenol; ketones such as acetone, 2-butanone, 3-methyl-2-butanone, 4-methyl-2-pentanone, 2-heptanone, cyclopentanone, cyclohexanone, and methylcyclohexanone; and the like. These solvents may be used either individually or in combination.

The reaction (polymerization) temperature is normally 40 to 150° C., and preferably 50 to 120° C. The reaction (polymerization) time is normally 1 to 48 hours, and preferably 1 to 24 hours. It is preferable that the resist resin have an impurity (e.g., halogen and metal) content as low as possible in order to improve the sensitivity, the resolution, the process stability, the pattern profile, and the like. The resist resin may be purified by chemical purification (e.g., washing with water or liquid-liquid extraction) or a combination of chemical purification and physical purification (e.g., ultrafiltration or centrifugation), for example.

The Mw of the resist resin is normally 1000 to 500,000, preferably 1000 to 100,000, and still more preferably 1000 to 50,000. If the Mw of the resist resin is less than 1000, the heat resistance of the resulting resist pattern may decrease. If the Mw of the resist resin exceeds 500,000, the developability may decrease. The ratio (Mw/Mn) of the Mw to the polystyrene-reduced number average molecular weight (Mn) of the resist resin determined by gel permeation chromatography (GPC) is preferably 1 to 5, and more preferably 1 to 3. The content (solid content) of a low-molecular-weight component that is included in the resist resin and contains a monomer as the main component is preferably 0.1 mass % or less based on the total amount of the resist resin. The content of a low-molecular-weight component may be determined by high-performance liquid chromatography (HPLC), for example.

### 2. Acid Generator

The acid generator decomposes and generates an acid upon exposure.

The content of the acid generator in the resist material is normally 0.1 to 20 parts by mass, and preferably 0.5 to 10 parts by mass, based on 100 parts by mass of the resist resin, so that the resist material exhibits excellent sensitivity and develop ability. If the content of the acid generator is less than 0.1 parts by mass, the sensitivity and the developability of the resist material may decrease. If the content of the acid generator exceeds 20 parts by mass, it may be difficult to form a rectangular resist pattern due to a decrease in transparency to radiation.

### (1) Acid Generator (1)

The acid generator is preferably an acid generator having a structure shown by the following general formula (10) (hereinafter may be referred to as “acid generator (1)”).

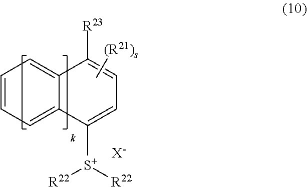

wherein R²¹ represents a linear or branched alkyl group or alkoxy group having 1 to 10 carbon atoms or a linear, branched, or cyclic alkanesulfonyl group having 1 to 10 carbon atoms, R²² individually represent a linear or branched alkyl group having 1 to 10 carbon atoms, a substituted or unsubstituted phenyl group, or a substituted or unsubstituted naphthyl group, or bond to form a substituted or unsubstituted divalent group having 2 to 10 carbon atoms that includes the sulfur cation, R²³ represents a hydrogen atom, a fluorine atom, a hydroxyl group, a linear or branched alkyl group having 1 to 10 carbon atoms, a linear or branched alkoxy group having 1 to 10 carbon atoms, or a linear or branched alkoxycarbonyl group having 2 to 11 carbon atoms, k is an integer from 0 to 2, X⁻ represents an anion shown by the general formula (11): R²⁴CₙF₂ₙSO₃⁻ (wherein R²⁴ represents a fluorine atom or a substituted or unsubstituted hydrocarbon group having 1 to 12 carbon atoms, and n is an integer from 1 to 10), and s is an integer from 0 to 10 (preferably an integer from 0 to 2).

Examples of the linear or the branched alkyl group having 1 to 10 carbon atoms represented by R²¹ to R²³ in the general formula (10) include a methyl group, an ethyl group, an n-propyl group, an i-propyl group, an n-butyl group, a 2-methylpropyl group, a 1-methylpropyl group, a t-butyl group, an n-pentyl group, a neopentyl group, an n-hexyl group, an n-heptyl group, an n-octyl group, a 2-ethylhexyl group, an n-nonyl group, an n-decyl group, and the like. Among these, a methyl group, an ethyl group, an n-butyl group, and a t-butyl group are preferable.

Examples of the linear or branched alkoxy group having 1 to 10 carbon atoms represented by R²¹ and R²³ in the general formula (10) include a methoxy group, an ethoxy group, an n-propoxy group, an i-propoxy group, an n-butoxy group, a 2-methylpropoxy group, a 1-methylpropoxy group, a t-butoxy group, an n-pentyloxy group, a neopentyloxy group, an n-hexyloxy group, an n-heptyloxy group, an n-octyloxy group, a 2-ethylhexyloxy group, an n-nonyloxy group, an n-decyloxy group, and the like. Among these, a methoxy group, an ethoxy group, an n-propoxy group, and an n-butoxy group are preferable.

Examples of the linear or branched alkoxycarbonyl group having 2 to 11 carbon atoms represented by R²³ in the general formula (10) include a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, an n-pentyloxycarbonyl group, a neopentyloxycarbonyl group, an n-hexyloxycarbonyl group, an n-heptyloxycarbonyl group, an n-octyloxycarbonyl group, a 2-ethylhexyloxycarbonyl group, an n-nonyloxycarbonyl group, an n-decyloxycarbonyl group, and the like. Among these, a methoxycarbonyl group, an ethoxycarbonyl group, and an n-butoxycarbonyl group are preferable.

Examples of the linear, branched, or cyclic alkanesulfonyl group having 1 to 10 carbon atoms represented by R²¹ in the general formula (10) include a methanesulfonyl group, an ethanesulfonyl group, an n-propanesulfonyl group, an n-butanesulfonyl group, a tert-butanesulfonyl group, an n-pentanesulfonyl group, a neopentanesulfonyl group, an n-hexanesulfonyl group, an n-heptanesulfonyl group, an n-octanesulfonyl group, a 2-ethylhexanesulfonyl group, an n-nonanesulfonyl group, an n-decanesulfonyl group, a cyclopentanesulfonyl group, a cyclohexanesulfonyl group, and the like. Among these, a methanesulfonyl group, an ethanesulfonyl group, an n-propanesulfonyl group, an n-butanesulfonyl group, a cyclopentanesulfonyl group, and a cyclohexanesulfonyl group are preferable.

Examples of the substituted or unsubstituted phenyl group represented by R²² in the general formula (10) include a phenyl group; phenyl groups substituted with a linear, branched, or cyclic alkyl group having 1 to 10 carbon atoms, such as an o-tolyl group, an m-tolyl group, a p-tolyl group, a 2,3-dimethylphenyl group, a 2,4-dimethylphenyl group, a 2,5-dimethylphenyl group, a 2,6-dimethylphenyl group, a 3,4-dimethylphenyl group, a 3,5-dimethylphenyl group, a 2,4,6-trimethylphenyl group, a 4-ethylphenyl group, a 4-t-butylphenyl group, 4-cyclohexylphenyl group, and a 4-fluorophenyl group; groups obtained by substituting a phenyl group or the alkyl-substituted phenyl groups with at least one group selected from a hydroxyl group, a carboxyl group, a cyano group, a nitro group, an alkoxy group, an alkoxyalkyl group, an alkoxycarbonyl group, and an alkoxycarbonyloxy group; and the like.

Examples of the alkoxy group as a substituent for a phenyl group or the alkyl-substituted phenyl groups include linear, branched, or cyclic alkoxy groups having 1 to 20 carbon atoms, such as a methoxy group, an ethoxy group, an n-propoxy group, an i-propoxy group, an n-butoxy group, a 2-methylpropoxy group, a 1-methylpropoxy group, a t-butoxy group, a cyclopentyloxy group, and a cyclohexyloxy group, and the like.

Examples of the alkoxyalkyl group include linear, branched, or cyclic alkoxyalkyl groups having 2 to 21 carbon atoms, such as a methoxymethyl group, an ethoxymethyl group, a 1-methoxyethyl group, a 2-methoxyethyl group, a 1-ethoxyethyl group, and a 2-ethoxyethyl group, and the like. Examples of the alkoxycarbonyl group include linear, branched, or cyclic alkoxycarbonyl groups having 2 to 21 carbon atoms, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a t-butoxycarbonyl group, a cyclopentyloxycarbonyl group, and a cyclohexyloxycarbonyl group, and the like.

Examples of the alkoxycarbonyloxy group include linear, branched, or cyclic alkoxycarbonyloxy groups having 2 to 21 carbon atoms, such as a methoxycarbonyloxy group, an ethoxycarbonyloxy group, an n-propoxycarbonyloxy group, an i-propoxycarbonyloxy group, an n-butoxycarbonyloxy group, a t-butoxycarbonyloxy group, and a cyclopentyloxycarbonyloxy group, and a cyclohexyloxycarbonyloxy group, and the like. The substituted or unsubstituted phenyl group represented by R²² in the general formula (10) is preferably a phenyl group, a 4-cyclohexylphenyl group, a 4-t-butylphenyl group, a 4-methoxyphenyl group, a 4-t-butoxyphenyl group, or the like.

Examples of the substituted or unsubstituted naphthyl group represented by R²² in the general formula (10) include naphthyl groups substituted or unsubstituted with a linear, branched, or cyclic alkyl group having 1 to 10 carbon atoms, such as a 1-naphthyl group, a 2-methyl-1-naphthyl group, a 3-methyl-1-naphthyl group, a 4-methyl-1-naphthyl group, a 5-methyl-1-naphthyl group, a 6-methyl-1-naphthyl group, a 7-methyl-1-naphthyl group, a 8-methyl-1-naphthyl group, a 2,3-dimethyl-1-naphthyl group, a 2,4-dimethyl-1-naphthyl group, a 2,5-dimethyl-1-naphthyl group, a 2,6-dimethyl-1-naphthyl group, a 2,7-dimethyl-1-naphthyl group, a 2,8-dimethyl-1-naphthyl group, a 3,4-dimethyl-1-naphthyl group, a 3,5-dimethyl-1-naphthyl group, a 3,6-dimethyl-1-naphthyl group, a 3,7-dimethyl-1-naphthyl group, a 3,8-dimethyl-1-naphthyl group, a 4,5-dimethyl-1-naphthyl group, a 5,8-dimethyl-1-naphthyl group, a 4-ethyl-1-naphthyl group, a 2-naphthyl group, a 1-methyl-2-naphthyl group, a 3-methyl-2-naphthyl group, and a 4-methyl-2-naphthyl group; groups obtained by substituting a naphthyl group or the alkyl-substituted naphthyl groups with at least one group such as a hydroxyl group, a carboxyl group, a cyano group, a nitro group, an alkoxyl group, an alkoxyalkyl group, an alkoxycarbonyl group, or an alkoxycarbonyloxy group; and the like. Specific examples of the alkoxy group, the alkoxyalkyl group, the alkoxycarbonyl group, and the alkoxycarbonyloxy group as a substituent include the groups mentioned above in connection with a phenyl group and the alkyl-substituted phenyl groups.

The substituted or unsubstituted naphthyl group represented by R²² in the general formula (10) is preferably a 1-naphthyl group, a 1-(4-methoxynaphthyl) group, a 1-(4-ethoxynaphthyl) group, a 1-(4-n-propoxynaphthyl) group, a 1-(4-n-butoxynaphthyl) group, a 2-(7-methoxynaphthyl) group, a 2-(7-ethoxynaphthyl) group, a 2-(7-n-propoxynaphthyl) group, a 2-(7-n-butoxynaphthyl) group, or the like.

The sulfur cation-containing divalent group having 2 to 10 carbon atoms formed by the two R²² in the general formula (10) is preferably a group that forms a five- or six-membered ring (preferably a five-membered ring (i.e., tetrahydrothiophene ring)) together with the sulfur cation in the general formula (10). Examples of a substituent for the divalent group include the groups (e.g., hydroxyl group, carboxyl group, cyano group, nitro group, alkoxy group, alkoxyalkyl group, alkoxycarbonyl group, and alkoxycarbonyloxy group) mentioned above in connection with a phenyl group and the alkyl-substituted phenyl group. Note that it is preferable that R²² in the general formula (10) be a methyl group, an ethyl group, a phenyl group, a 4-methoxyphenyl group, or a 1-naphthyl group, or bond to form a divalent group that forms a tetrahydrothiophene ring structure together with the sulfur cation.

Preferable examples of the cation moiety in the general formula (10) include a triphenylsulfonium cation, a tri-1-naphthylsulfonium cation, a tri-tert-butylphenylsulfonium cation, a 4-fluorophenyl-diphenylsulfonium cation, a di-4-fluorophenyl-phenylsulfonium cation, a tri-4-fluorophenylsulfonium cation, a 4-cyclohexylphenyl-diphenylsulfonium cation, a 4-methanesulfonylphenyl-diphenylsulfonium cation, a 4-cyclohexanesulfonyl-diphenylsulfonium cation, a 1-naphthyldimethylsulfonium cation, a 1-naphthyldiethylsulfonium cation, a 1-(4-hydroxynaphthyl)dimethylsulfonium cation, a 1-(4-methylnaphthyl)dimethylsulfonium cation, a 1-(4-methylnaphthyl)diethylsulfonium cation, a 1-(4-cyanonaphthyl)dimethylsulfonium cation, a 1-(4-cyanonaphthyl)diethylsulfonium cation, a 1-(3,5-dimethyl-4-hydroxyphenyl)tetrahydrothiophenium cation, a 1-(4-methoxynaphthyl)tetrahydrothiophenium cation, a 1-(4-ethoxynaphthyl)tetrahydrothiophenium cation, a 1-(4-n-propoxynaphthyl)tetrahydrothiophenium cation, a 1-(4-n-butoxynaphthyl)tetrahydrothiophenium cation, a 2-(7-methoxynaphthyl)tetrahydrothiophenium cation, a 2-(7-ethoxynaphthyl)tetrahydrothiophenium cation, a 2-(7-n-propoxynaphthyl)tetrahydrothiophenium cation, a 2-(7-n-butoxynaphthyl)tetrahydrothiophenium cation, and the like.

The group “CₙF₂ₙ—” in the anion (general formula (11): R²⁴CₙF₂ₙSO₃⁻) represented by X⁻ in the general formula (10) is a perfluoroalkylene group having n carbon atoms. The perfluoroalkylene group may be linear or branched. n is preferably 1, 2, 4, or 8. The substituted or unsubstituted hydrocarbon group having 1 to 12 carbon atoms represented by R²⁴ is preferably an alkyl group, a cycloalkyl group, or a bridged alicyclic hydrocarbon group having 1 to 12 carbon atoms. Specific examples of the substituted or unsubstituted hydrocarbon group having 1 to 12 carbon atoms include a methyl group, an ethyl group, an n-propyl group, an i-propyl group, an n-butyl group, a 2-methylpropyl group, a 1-methylpropyl group, a t-butyl group, an n-pentyl group, an neopentyl group, an n-hexyl group, a cyclohexyl group, an n-heptyl group, an n-octyl group, a 2-ethylhexyl group, an n-nonyl group, an n-decyl group, a norbornyl group, a norbornylmethyl group, a hydroxynorbornyl group, an adamantyl group, and the like.

Preferable examples of the anion moiety in the general formula (10) include a trifluoromethanesulfonate anion, a perfluoro-n-butanesulfonate anion, a perfluoro-n-octanesulfonate anion, a 2-bicyclo[2.2.1]hept-2-yl-1,1,2,2-tetrafluoroethanesulfonate anion, a 2-bicyclo[2.2.1]hept-2-yl-1,1-difluoroethanesulfonate anion, and the like.

These acid generators (1) may be used either individually or in combination.

### (2) Additional Acid Generator

An additional acid generator other than the acid generator (1) may also be used. Examples of the additional acid generator include onium salt compounds, halogen-containing compounds, diazoketone compounds, sulfone compounds, sulfonic acid compounds, and the like.

Examples of the onium salt compounds include iodonium salts, sulfonium salts, phosphonium salts, diazonium salts, pyridinium salts, and the like. Specific examples of the onium salt compounds include diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, cyclohexyl-2-oxocyclohexyl•methylsulfonium trifluoromethanesulfonate, dicyclohexyl-2-oxocyclohexylsulfonium trifluoromethanesulfonate, 2-oxocyclohexyldimethylsulfonium trifluoromethanesulfonate, and the like.

Examples of the halogen-containing compounds include a haloalkyl group-containing hydrocarbon compounds, haloalkyl group-containing heterocyclic compounds, and the like. Specific examples of the halogen-containing compounds include (trichloromethyl)-s-triazine derivatives such as phenylbis(trichloromethyl)-s-triazine, 4-methoxyphenylbis(trichloromethyl)-s-triazine, and 1-naphthylbis(trichloromethyl)-s-triazine, 1,1-bis(4-chlorophenyl)-2,2,2-trichloroethane, and the like.

Examples of the diazoketone compounds include 1,3-diketo-2-diazo compounds, diazobenzoquinone compounds, diazonaphthoquinone compounds, and the like. Specific examples of the diazoketone compounds include 1,2-naphthoquinonediazide-4-sulfonyl chloride, 1,2-naphthoquinonediazide-5-sulfonyl chloride, 1,2-naphthoquinonediazide-4-sulfonate or 1,2-naphthoquinonediazide-5-sulfonate of 2,3,4,4′-tetrahydroxybenzophenone, 1,2-naphthoquinonediazide-4-sulfonate or 1,2-naphthoquinonediazide-5-sulfonate of 1,1,1-tris(4-hydroxyphenyl)ethane, and the like.

Examples of the sulfone compounds include β-ketosulfone, β-sulfonylsulfone, α-diazo compounds thereof, and the like. Specific examples of the sulfone compounds include 4-trisphenacylsulfone, mesitylphenacylsulfone, bis(phenylsulfonyl)methane, and the like.

Examples of the sulfonic acid compounds include alkyl sulfonates, alkylimide sulfonates, haloalkyl sulfonates, aryl sulfonates, imino sulfonates, and the like. Specific examples of the sulfonic acid compounds include benzointosylate, tris(trifluoromethanesulfonate) of pyrogallol, nitrobenzyl-9,10-diethoxyanthracene-2-sulfonate, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, 2-bicyclo[2.2.1]hept-2-yl-1,1,2,2-tetrafluoroethanesulfonylbicyclo[2.2.1]hept-5-ene-2,3-dicarbodiimide, N-(trifluoromethanesulfonyloxy)succinimide, N-(nonafluoro-n-butanesulfonyloxy)succinimide, N-(perfluoro-n-octanelsulfonyloxy)succinimide, N-(2-bicyclo[2.2.1]hept-2-yl-1,1,2,2-tetrafluoroethanesulfonyloxy)succinimide, 1,8-naphthalenedicarboxylic acid imide trifluoromethanesulfonate, 1,8-naphthalenedicarboxylic acid imide nonafluoro-n-butanesulfonate, 1,8-naphthalenedicarboxylic acid imide perfluoro-n-octanesulfonate, and the like.

Among these, diphenyliodonium trifluoromethanesulfonate, diphenyliodonium nonafluoro-n-butanesulfonate, diphenyliodonium perfluoro-n-octanesulfonate, diphenyliodonium 2-bicyclo[2.2.1]hept-2-yl-1,1,2,2-tetrafluoroethanesulfonate, bis(4-t-butylphenyl)iodonium trifluoromethanesulfonate, bis(4-t-butylphenyl)iodonium nonafluoro-n-butanesulfonate, bis(4-t-butylphenyl)iodonium perfluoro-n-octanesulfonate, bis(4-t-butylphenyl)iodonium 2-bicyclo[2.2.1]hept-2-yl-1,1,2,2-tetrafluoroethanesulfonate, cyclohexyl-2-oxocyclohexylmethylsulfonium trifluoromethanesulfonate, dicyclohexyl•2-oxocyclohexylsulfonium trifluoromethanesulfonate, 2-oxocyclohexyldimethylsulfonium trifluoromethanesulfonate, trifluoromethanesulfonylbicyclo[2.2.1]hept-5-ene-2,3-dicarbodiimide, nonafluoro-n-butanesulfonylbicyclo[2.2.1]hept-5-ene-2,3-dicarbodiimide, perfluoro-n-octanesulfonylbicyclo[2.2.1]hept-5-ene-2,3-dicarbodiimide, 2-bicyclo[2.2.1]hept-2-yl-1,1,2,2-tetrafluoroethanesulfonylbicyclo[2.2.1]hept-5-ene-2,3-dicarbodiimide, N-(trifluoromethanesulfonyloxy)succinimide, N-(nonafluoro-n-butanesulfonyloxy)succinimide, N-(perfluoro-n-octanesulfonyloxy)succinimide, N-(2-bicyclo[2.2.1]hept-2-yl-1,1,2,2-tetrafluoroethanesulfonyloxy)succinimide, 1,8-naphthalenedicarboxylic acid imide trifluoromethanesulfonate, and the like are preferable. These additional acid generators may be used either individually or in combination.

The acid generator (1) may be used in combination with the additional acid generator. In this case, the additional acid generator is normally used in an amount of 80 mass % or less, and preferably 60 mass % or less, based on the total amount of the acid generator (1) and the additional acid generator.

### 3. Solvent

The resist material is prepared by dissolving the resist resin, the acid generator, an optional acid diffusion controller, and the like in a solvent. The solvent is preferably at least one compound selected from the group consisting of propylene glycol monomethyl ether acetate, 2-heptanone, and cyclohexanone (hereinafter may be referred to as “solvent (1)”). A solvent (hereinafter may be referred to as “solvent (2)”) other than the solvent (1) may also be used. It is also possible to use the solvents (1) and (2) in combination.

Examples of the solvent (2) include propylene glycol monoalkyl ether acetates such as propylene glycol monoethyl ether acetate, propylene glycol mono-n-propyl ether acetate, propylene glycol mono-i-propyl ether acetate, propylene glycol mono-n-butyl ether acetate, propylene glycol mono-i-butyl ether acetate, propylene glycol mono-sec-butyl ether acetate, and propylene glycol mono-t-butyl ether acetate; linear or branched ketones such as 2-butanone, 2-pentanone, 3-methyl-2-butanone, 2-hexanone, 4-methyl-2-pentanone, 3-methyl-2-pentanone, 3,3-dimethyl-2-butanone, and 2-octanone; cyclic ketones such as cyclopentanone, 3-methylcyclopentanone, 2-methylcyclohexanone, 2,6-dimethylcyclohexanone, and isophorone; alkyl 2-hydroxypropionates such as methyl 2-hydroxypropionate, ethyl 2-hydroxypropionate, n-propyl 2-hydroxypropionate, i-propyl 2-hydroxypropionate, n-butyl 2-hydroxypropionate, i-butyl 2-hydroxypropionate, sec-butyl 2-hydroxypropionate, and t-butyl 2-hydroxypropionate; alkyl 3-alkoxypropionates such as methyl 3-methoxypropionate, ethyl 3-methoxypropionate, methyl 3-ethoxypropionate, and ethyl 3-ethoxypropionate; n-propyl alcohol, i-propyl alcohol, n-butyl alcohol, t-butyl alcohol, cyclohexanol, ethylene glycol monomethyl ether, ethylene glycol monoethyl ether, ethylene glycol mono-n-propyl ether, ethylene glycol mono-n-butyl ether, diethylene glycol dimethyl ether, diethylene glycol diethyl ether, diethylene glycol di-n-propyl ether, diethylene glycol di-n-butyl ether, ethylene glycol monomethyl ether acetate, ethylene glycol monoethyl ether acetate, ethylene glycol mono-n-propyl ether acetate, propylene glycol monomethyl ether, propylene glycol monoethyl ether, propylene glycol mono-n-propyl ether, toluene, xylene, ethyl 2-hydroxy-2-methylpropionate, ethoxyethyl acetate, ethyl hydroxyacetate, methyl 2-hydroxy-3-methylbutyrate, 3-methoxybutylacetate, 3-methyl-3-methoxybutylacetate, 3-methyl-3-methoxybutylpropionate, 3-methyl-3-methoxybutylbutyrate, ethyl acetate, n-propyl acetate, n-butyl acetate, methyl acetoacetate, ethyl acetoacetate, methyl pyruvate, ethyl pyruvate, N-methylpyrrolidone, N,N-dimethylformamide, N,N-dimethylacetamide, benzyl ethyl ether, di-n-hexyl ether, diethylene glycol monomethyl ether, diethylene glycol monoethyl ether, caproic acid, caprylic acid, 1-octanol, 1-nonanol, benzyl alcohol, benzyl acetate, ethyl benzoate, diethyl oxalate, diethyl maleate, γ-butyrolactone, ethylene carbonate, propylene carbonate, and the like.

Among these, linear or branched ketones, cyclic ketones, propylene glycol monoalkyl ether acetates, alkyl 2-hydroxypropionates, alkyl 3-alkoxypropionates, γ-butyrolactone, and the like are preferable. These solvents (2) may be used either individually or in combination.

When using the solvents (1) and (2) in combination, the solvent (2) is normally used in an amount of 50 mass % or less, preferably 30 mass % or less, and still more preferably 25 mass % or less, based on the total amount of the solvents. The solvent is normally used in such an amount that the resist material has a solid content of 2 to 70 mass %, preferably 4 to 25 mass %, and more preferably 4 to 10 mass %.

### 4. Acid Diffusion Controller

It is preferable that the resist material include an acid diffusion controller. The acid diffusion controller controls diffusion of an acid generated from the acid generator upon exposure within the resist layer, and suppresses undesired chemical reactions in the unexposed area. The acid diffusion controller improves the storage stability of the resist material and the resolution of the resist, and suppresses a change in line width of the resist pattern due to a variation in post-exposure delay (PED) from exposure to post-exposure bake. Therefore, a composition that exhibits excellent process stability can be obtained. A nitrogen-containing organic compound or a photodegradable base is preferably used as the acid diffusion controller. The term “photodegradable base” used herein refers to an onium salt compound that exhibits acid diffusion controllability upon decomposition due to exposure.

The acid diffusion controller is normally used in an amount of 15 parts by mass or less, preferably 10 parts by mass or less, and still more preferably 5 parts by mass or less, based on 100 parts by mass of the resist resin. If the amount of the acid diffusion controller exceeds 15 parts by mass, the resolution of the resist material may decrease. If the amount of the acid diffusion controller is less than 0.001 parts by mass, the shape or the dimensional accuracy of the resist pattern may decrease depending on the process conditions.

### (1) Nitrogen-Containing Organic Compound

Examples of the nitrogen-containing organic compound include a compound shown by the following general formula (12) (hereinafter referred to as “nitrogen-containing compound (1)”), a compound that includes two nitrogen atoms in the molecule (hereinafter referred to as “nitrogen-containing compound (2)”), a polyamino compound that includes three or more nitrogen atoms in the molecule and a polymer thereof (hereinafter collectively referred to as “nitrogen-containing compound (3)”), amide group-containing compounds, urea compounds, nitrogen-containing heterocyclic compounds, and the like.

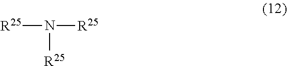

wherein R²⁵ individually represent a hydrogen atom, a substituted or unsubstituted linear, branched, or cyclic alkyl group, a substituted or unsubstituted aryl group, or a substituted or unsubstituted aralkyl group.

Preferable examples of the nitrogen-containing compound (1) include mono(cyclo)alkylamines such as n-hexylamine, n-heptylamine, n-octylamine, n-nonylamine, n-decylamine, and cyclohexylamine; di(cyclo)alkylamines such as di-n-butylamine, di-n-pentylamine, di-n-hexylamine, di-n-heptylamine, di-n-octylamine, di-n-nonylamine, di-n-decylamine, cyclohexylmethylamine, and dicyclohexylamine; tri(cyclo)alkylamines such as triethylamine, tri-n-propylamine, tri-n-butylamine, tri-n-pentylamine, tri-n-hexylamine, tri-n-heptylamine, tri-n-octylamine, tri-n-nonylamine, tri-n-decylamine, cyclohexyldimethylamine, methyldicyclohexylamine, and tricyclohexylamine; and substituted alkylamines such as 2,2′,2″-nitrotriethanol; and aromatic amines such as aniline, N-methylaniline, N,N-dimethylaniline, 2-methylaniline, 3-methylaniline, 4-methylaniline, 4-nitroaniline, diphenylamine, triphenylamine, naphthylamine, 2,4,6-tri-tert-butyl-N-methylaniline, N-phenyldiethanolamine, and 2,6-diisopropylaniline.

Preferable examples of the nitrogen-containing compound (2) include ethylenediamine, N,N,N′,N′-tetramethylethylenediamine, tetramethylenediamine, hexamethylenediamine, 4,4′-diaminodiphenylmethane, 4,4′-diamino diphenyl ether, 4,4′-diaminobenzophenone, 4,4′-diaminodiphenylamine, 2,2-bis(4-aminophenyl)propane, 2-(3-aminophenyl)-2-(4-aminophenyl)propane, 1,4-bis[1-(4-aminophenyl)-1-methylethyl]benzene, 1,3-bis[1-(4-aminophenyl)-1-methylethyl]benzene, bis(2-dimethylaminoethyl)ether, bis(2-diethylaminoethyl)ether, 1-(2-hydroxyethyl)-2-imidazolizinone, 2-quinoxalinol, N,N,N′,N′-tetrakis(2-hydroxypropyl)ethylenediamine, N,N,N′,N″,N″-pentamethyldiethylenetriamine, and the like.

Preferable examples of the nitrogen-containing compound (3) include polyethyleneimine, polyallylamine, a polymer of 2-dimethylaminoethylacrylamide, and the like.

Preferable examples of the amide group-containing compound include N-t-butoxycarbonyl group-containing amino compounds such as N-t-butoxycarbonyl di-n-octylamine, N-t-butoxycarbonyl di-n-nonylamine, N-t-butoxycarbonyl di-n-decylamine, N-t-butoxycarbonyl dicyclohexylamine, N-t-butoxycarbonyl-1-adamantylamine, N-t-butoxycarbonyl-2-adamantylamine, N-t-butoxycarbonyl-N-methyl-1-adamantylamine, (S)-(−)-1-(t-butoxycarbonyl)-2-pyrrolidine methanol, (R)-(+)-1-(t-butoxycarbonyl)-2-pyrrolidine methanol, N-t-butoxycarbonyl-4-hydroxypiperidine, N-t-butoxycarbonylpyrrolidine, N-t-butoxycarbonylpiperazine, N,N-di-t-butoxycarbonyl-1-adamantylamine, N,N-di-t-butoxycarbonyl-N-methyl-1-adamantylamine, N-t-butoxycarbonyl-4,4′-diaminodiphenylmethane, N,N′-di-t-butoxycarbonylhexamethylenediamine, N,N,N′N′-tetra-t-butoxycarbonylhexamethylenediamine, N,N′-di-t-butoxycarbonyl-1,7-diaminoheptane, N,N′-di-t-butoxycarbonyl-1,8-diaminonooctane, N,N′-di-t-butoxycarbonyl-1,9-diaminononane, N,N′-di-t-butoxycarbonyl-1,10-diaminodecane, N,N′-di-t-butoxycarbonyl-1,12-diaminododecane, N,N′-di-t-butoxycarbonyl-4,4′-diaminodiphenylmethane, N-t-butoxycarbonylbenzimidazole, N-t-butoxycarbonyl-2-methylbenzimidazole, N-t-butoxycarbonyl-2-phenylbenzimidazole, and N-t-butoxycarbonylpyrrolidine; formamide, N-methylformamide, N,N-dimethylformamide, acetamide, N-methylacetamide, N,N-dimethylacetamide, propionamide, benzamide, pyrrolidone, N-methylpyrrolidone, N-acetyl-1-adamantylamine, tris(2-hydroxyethyl)isocyanuric acid, and the like.

Preferable examples of the urea compound include urea, methylurea, 1,1-dimethylurea, 1,3-dimethylurea, 1,1,3,3-tetramethylurea, 1,3-diphenylurea, tri-n-butylthiourea, and the like. Preferable examples of the nitrogen-containing heterocyclic compound include imidazoles such as imidazole, 4-methylimidazole, 4-methyl-2-phenylimidazole, benzimidazole, 2-phenylbenzimidazole, 1-benzyl-2-methylimidazole, and 1-benzyl-2-methyl-1H-imidazole; pyridines such as pyridine, 2-methylpyridine, 4-methylpyridine, 2-ethylpyridine, 4-ethylpyridine, 2-phenylpyridine, 4-phenylpyridine, 2-methyl-4-phenylpyridine, nicotine, nicotinic acid, nicotinic acid amide, quinoline, 4-hydroxyquinoline, 8-oxyquinoline, acridine, and 2,2′:6′,2″-terpyridine; piperazines such as piperazine and 1-(2-hydroxyethyl)piperazine; and pyrazine, pyrazole, pyridazine, quinoxaline, purine, pyrrolidine, piperidine, piperidineethanol, 3-piperidino-1,2-propanediol, morpholine, 4-methylmorpholine, 1-(4-morpholinyl)ethanol, 4-acetylmorpholine, 3-(N-morpholino)-1,2-propanediol, 1,4-dimethylpiperazine, 1,4-diazabicyclo[2.2.2]octane, and the like.

### (2) Photodegradable Base

The photodegradable base is an onium salt compound that loses acid diffusion controllability upon decomposition due to exposure. Specific examples of the onium salt compound include a sulfonium salt compound shown by the following general formula (13) and an iodonium salt compound shown by the following general formula (14).

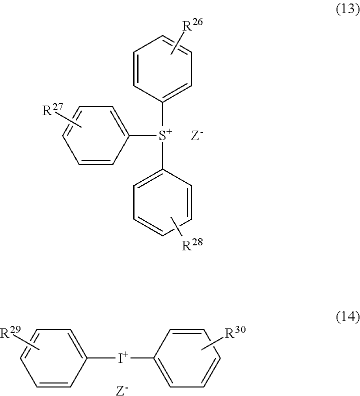

wherein R²⁶ to R³⁰ individually represent a hydrogen atom, an alkyl group, an alkoxy group, a hydroxyl group, or a halogen atom, and Z⁻ represents OH⁻, R³¹—COO⁻, R³¹—SO₃⁻ (wherein R³¹ represents an alkyl group, an aryl group, or an alkaryl group), or an anion shown by the following general formula (15).

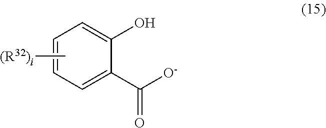

wherein R³² represents a linear or branched alkyl group having 1 to 12 carbon atoms that may be substituted with a fluorine atom, or a linear or branched alkoxy group having 1 to 12 carbon atoms, and i is an integer from 0 to 2.

Examples of the linear or the branched alkyl group having 1 to 12 carbon atoms that may be substituted with a fluorine atom, and the linear or branched alkoxy group having 1 to 12 carbon atoms represented by R³² in the general formula (15) include a methyl group, an ethyl group, an n-propyl group, an i-propyl group, an n-butyl group, a 2-methylpropyl group, a 1-methylpropyl group, a t-butyl group, a methoxy group, an ethoxy group, an n-propoxy group, an i-propoxy group, an n-butoxy group, a 2-methylpropoxy group, a 1-methylpropoxy group, a t-butoxy group, a trifluoromethyl group, a pentafluoroethyl group, a heptafluoropropyl group, a nonafluorobutyl group, a dodecafluoropentyl group, a perfluorooctyl group, and the like. Among these, a methyl group, a trifluoromethyl group, a pentafluoroethyl group, a heptafluoropropyl group, and a nonafluorobutyl group are preferable, and a trifluoromethyl group is particularly preferable. i is an integer from 0 to 2, and preferably 0 or 1.

These acid diffusion controllers may be used either individually or in combination.

### 5. Additive

The resist material may optionally include additives such as a surfactant, a sensitizer, and an aliphatic additive.

### (1) Surfactant

The surfactant improves the applicability, striation, developability, and the like. Examples of the surfactant include nonionic surfactants such as polyoxyethylene lauryl ether, polyoxyethylene stearyl ether, polyoxyethylene oleyl ether, polyoxyethylene n-octylphenyl ether, polyoxyethylene n-nonylphenyl ether, polyethylene glycol dilaurate, and polyethylene glycol distearate; commercially available products such as KP341 (manufactured by Shin-Etsu Chemical Co., Ltd.), Polyflow No. 75, Polyflow No. 95 (manufactured by Kyoeisha Chemical Co., Ltd.), EFTOP EF301, EFTOP EF303, EFTOP EF352 (manufactured by JEMCO, Inc.), Megafac F171, Megafac F173 (manufactured by DIC Corporation), Fluorad FC430, Fluorad FC431 (manufactured by Sumitomo 3M Ltd.), Asahi Guard AG710, Surflon S-382, Surflon SC-101, Surflon SC-102, Surflon SC-103, Surflon SC-104, Surflon SC-105, Surflon SC-106 (manufactured by Asahi Glass Co., Ltd.); and the like. These surfactants may be used either individually or in combination. The surfactant is normally used in an amount of 2 parts by mass or less based on 100 parts by mass of the resist resin.

### (2) Sensitizer

The sensitizer absorbs the energy of radiation, and transmits the absorbed energy to the acid generator so that the amount of acid generated by the acid generator increases. The sensitizer improves the apparent sensitivity of the resist material. Examples of the sensitizer include carbazoles, acetophenones, benzophenones, naphthalenes, phenols, biacetyl, eosine, rose bengal, pyrenes, anthracenes, phenothiazines, and the like. These sensitizers may be used either individually or in combination. A dye or a pigment visualizes the latent image in the exposed area, and reduces the effects of halation during exposure. An adhesion improver improves adhesion to a substrate. The sensitizer is normally used in an amount of 50 parts by mass or less based on 100 parts by mass of the resist resin.

### (3) Alicyclic Additive

The alicyclic additive further improves the dry etching resistance, the pattern shape, adhesion to a substrate, and the like. Examples of the alicyclic additive that may be added to the resist material include alicyclic additives including an acid-dissociable group, alicyclic additives that do not include an acid-dissociable group, and the like. Specific examples of the alicyclic additive include adamantane derivatives such as 1-adamantanecarboxylic acid, 2-adamantanone, t-butyl-1-adamantanecarboxylate, t-butoxycarbonylmethyl 1-adamantanecarboxylate, α-butyrolactone 1-adamantanecarboxylate, di-t-butyl 1,3-adamantanedicarboxylate, t-butyl 1-adamantaneacetate, t-butoxycarbonylmethyl 1-adamantaneacetate, di-t-butyl 1,3-adamantanediacetate, and 2,5-dimethyl-2,5-di(adamantylcarbonyloxy)hexane; deoxycholates such as t-butyl deoxycholate, t-butoxycarbonylmethyl deoxycholate, 2-ethoxyethyl deoxycholate, 2-cyclohexyloxyethyl deoxycholate, 3-oxocyclohexyl deoxycholate, tetrahydropyranyl deoxycholate, and mevalonolactone deoxycholate; lithocholates such as t-butyl lithocholate, t-butoxycarbonylmethyl lithocholate, 2-ethoxyethyl lithocholate, 2-cyclohexyloxyethyl lithocholate, 3-oxocyclohexyl lithocholate, tetrahydropyranyl lithocholate, and mevalonolactone lithocholate; alkyl carboxylates such as dimethyl adipate, diethyl adipate, dipropyl adipate, di-n-butyl adipate, and di-t-butyl adipate; 3-(2-hydroxy-2,2-bis(trifluoromethyl)ethyl)tetracyclo[6.2.1.1^{3,6}.0^{2,7}]dodecane; and the like.

These alicyclic additives may be used either individually or in combination. The alicyclic additive is normally used in an amount of 50 parts by mass or less, and preferably 30 parts by mass or less, based on 100 parts by mass of the resist resin. If the amount of the alicyclic additive exceeds 50 parts by mass, the heat resistance of the resulting resist may decrease. Examples of other additives include an alkali-soluble resin, a low-molecular-weight alkali solubility controller that includes an acid-dissociable protecting group, a halation inhibitor, a preservation stabilizer, an antifoaming agent, and the like.

The resist material may be prepared by dissolving each component in the solvent so that the total solid content is within the above range to obtain a homogenous solution, and filtering the solution through a filter having a pore size of about 0.02 μm, for example.

### EXAMPLES

The invention is further described below by way of examples. Note that the invention is not limited to the following examples. In the examples, the unit “parts” refers to “parts by mass”, and the unit “%” refers to “mass %”, unless otherwise indicated. The property value measurement methods and the property evaluation methods employed in the examples and comparative examples are given below.

Weight average molecular weight (Mw) and number average molecular weight (Mn): The weight average molecular weight (Mw) and the number average molecular weight (Mn) were measured by gel permeation chromatography (GPC) using GPC columns manufactured by Tosoh Corp. (G2000HXL×2, G3000HXL×1, G4000HXL×1) (flow rate: 1.0 ml/min, eluant: tetrahydrofuran, column temperature: 40° C., standard: monodisperse polystyrene). The dispersity “Mw/Mn” was calculated from the Mw and Mn measurement results.
Low-molecular-weight component residual rate: The low-molecular-weight component residual rate was determined by high-performance liquid chromatography (HPLC) using an Intersil ODS-25 μm column (4.6 mm (diameter)×250 mm) (manufactured by GL Sciences Inc.) (flow rate: 1.0 ml/min, eluant: acrylonitrile/0.1% phosphoric acid aqueous solution).
Note that the term “low-molecular-weight component” refers to a component (mainly monomer) having a molecular weight of less than 1000 (preferably a component having a molecular weight equal to or lower than that of a trimer).
¹³C-NMR analysis: Each polymer was subjected to ¹³C-NMR analysis (solvent: CDCL₃) using an instrument “JNM-EX270” (manufactured by JEOL Ltd.).
Evaluation of pattern: A resist pattern formed on an evaluation substrate B or C was evaluated in accordance with the following standard using a scanning electron microscope (“S-9380” manufactured by Hitachi High-Technologies Corporation).

### (Evaluation Substrate B)

The presence or absence of a 50 nm line/200 nm pitch resist pattern (180 nm line/240 nm pitch in Reference Examples 19 to 23, and 50 nm space/200 nm pitch in Reference Example 24) was observed. A case where the first resist pattern remained was evaluated as “Good”, and a case where the first resist pattern was lost was evaluated as “Bad”. A case where the difference in size of the insolubilized resist pattern formed by treating the first resist pattern using the resist pattern coating agent (hereinafter referred to as “pattern dimensional change”) was within ±2 nm was evaluated as “Excellent”, and a case where the pattern dimensional change was within ±5 nm was evaluated as “Good”.

### (Evaluation Substrate C)

A case where a 50 nm line/100 nm pitch (50 nm 1L/1S) line-and-space pattern (a 60 nm hole/240 nm pitch contact hole pattern in Examples 34 to 37, a hole pattern formed by forming the second resist pattern at an arbitrary angle with respect to the first resist pattern in Example 38, or a contact hole pattern formed by forming a 50 nm trench/200 nm pitch resist pattern at an arbitrary angle with respect to the first resist pattern in Example 39) could be formed within the space area of the first resist pattern formed on the evaluation substrate B was evaluated as “Good”, and a case where (i) the first resist pattern was lost, (ii) the second resist pattern was not formed, or (iii) the second resist pattern was formed, but the first resist pattern remained undissolved was evaluated as “Bad”. In Examples 34 to 39, a case where a contact hole was formed was evaluated as “Good (hole)”.

### Synthesis Example 1

A monomer component including 50.4 g (50 mol %) of a monomer that produces the repeating unit shown by the following formula (m-1), 37.2 g (35 mol %) of a monomer that produces the repeating unit shown by the following formula (m-2), and 12.4 g (15 mol %) of a monomer that produces the repeating unit shown by the following formula (m-3), was dissolved in 200 g of 2-butanone. 4.03 g of azobisisobutyronitrile was added to the solution to prepare a monomer solution (1). A three-necked flask (1000 ml) was charged with 100 g of 2-butanone, purged with nitrogen for 30 minutes, and heated to 80° C. with stirring. The monomer solution (1) was added dropwise to the flask using a dropping funnel over three hours. The monomers were polymerized for six hours from the start of the addition of the monomer solution. After completion of polymerization, the polymer solution was cooled with water to 30° C. or less, and added to 2000 g of methanol. A precipitated white powder was collected by filtration. The white powder thus collected was washed twice with 400 g of methanol in a slurry state, collected by filtration, and dried at 50° C. for 17 hours to obtain a white powdery polymer (A-1) (75 g, yield: 75%). The Mw of the polymer (A-1) was 6900. As a result of ¹³C-NMR analysis, the polymer (A-1) was found to contain the repeating units shown by the following formula (A-1). The content (molar ratio) of the repeating units was a/b/c=50.9/34.6/14.5. The polymer (A-1) is referred to as “resist resin (A-1)”.

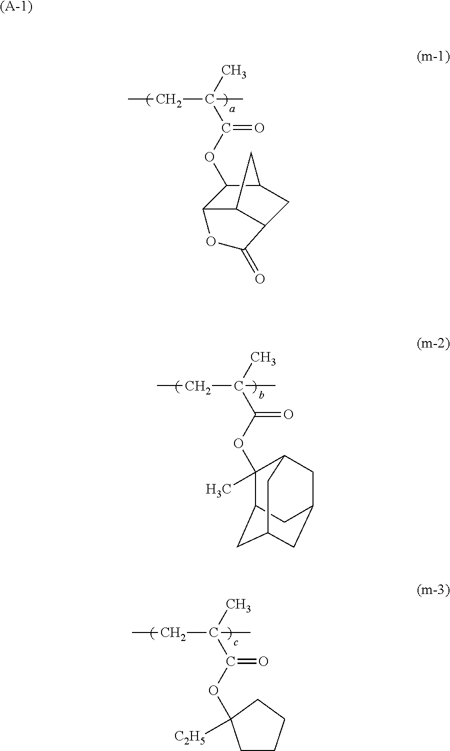

### Synthesis Example 2

A polymer (A-2) was prepared in the same manner as in Synthesis Example 1, except for using a monomer component including 40.17 g (40 mol %) of a monomer that produces the repeating unit shown by the formula (m-1), 37.06 g (45 mol %) of a monomer that produces the repeating unit shown by the following formula (m-4) instead of a monomer that produces the repeating unit shown by the formula (m-2), and 22.77 g (15 mol %) of a monomer that produces the repeating unit shown by the following formula (m-5) instead of a monomer that produces the repeating unit shown by the formula (m-3). The Mw of the polymer (A-2) was 6100. As a result of ¹³C-NMR analysis, the polymer (A-2) was found to contain the repeating units shown by the following formula (A-2). The content (molar ratio) of the repeating units was a/b/c=45.0/15.0/40.0. The polymer (A-2) is referred to as “resist resin (A-2)”.

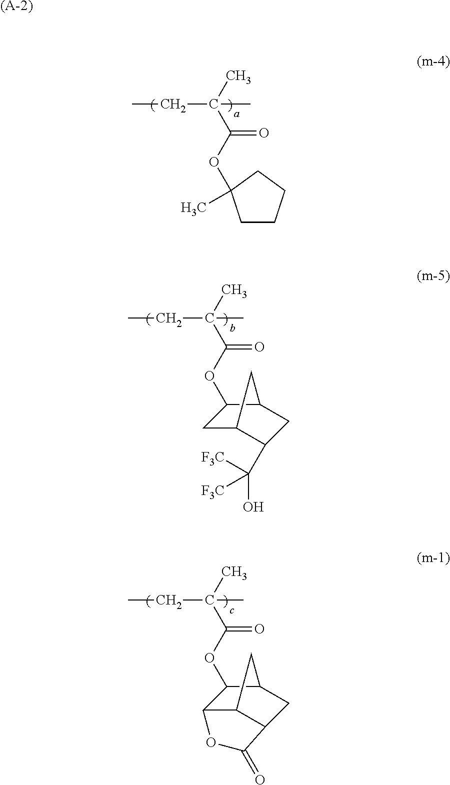

### Synthesis Example 3

A polymer (G-1) was prepared in the same manner as in Synthesis Example 1, except for using a monomer component including 68.01 g (70 mol %) of a monomer that produces the repeating unit shown by the formula (m-3) instead of a monomer that produces the repeating unit shown by the formula (m-1), and 31.99 g (30 mol %) of a monomer that produces the repeating unit shown by the following formula (m-6). The Mw of the polymer (G-1) was 7500. As a result of ¹³C-NMR analysis, the polymer (G-1) was found to contain the repeating units shown by the following formula (G-1). The content (molar ratio) of the repeating units was a/b=70.0/30.0. The polymer (G-1) is referred to as “additive (G-1)”.

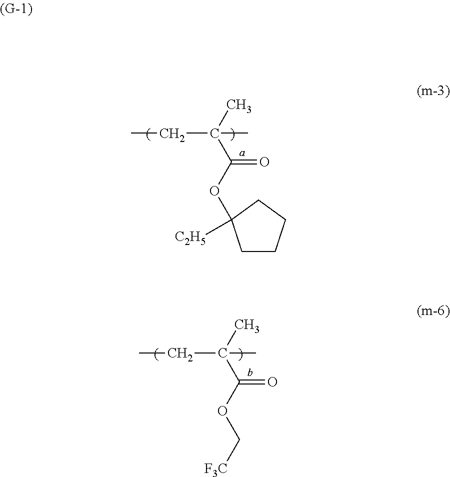

### (Preparation of Resist Material)

Resist materials (1) to (5) were prepared using the resist resin (A-1) or (A-2), an acid generator (D), an acid diffusion controller (E), a solvent (F), and the additive (G-1) in amounts shown in Table 1.

TABLE 1

| | | | Acid | | Acid diffusion | | | | | |
|---|---|---|---|---|---|---|---|---|---|---|
| | Resist resin | | generator (D) | | controller (E) | | Solvent (F) | | Additive (G) | |
| | | Amount | | Amount | | Amount | | Amount | | Amount |
| Resist | | (parts by | | (parts by | | (parts by | | (parts by | | (parts by |
| material | Type | mass) | Type | mass) | Type | mass) | Type | mass) | Type | mass) |
| (1) | A-1 | 100 | D-1 | 6 | E-1 | 1.4 | F-1 | 1500 | — | — |
| | | | D-3 | 1 | | | F-2 | 625 | | |
| | | | — | — | | | F-3 | 30 | | |
| (2) | A-2 | 100 | D-2 | 7 | E-2 | 3 | F-1 | 2125 | — | — |
| | | | | | | | F-3 | 30 | | |
| (3) | A-2 | 100 | D-2 | 7 | E-2 | 3 | F-1 | 2155 | — | — |
| (4) | A-2 | 100 | D-2 | 7 | E-2 | 3 | F-1 | 1500 | — | — |
| | | | | | | | F-2 | 625 | | |
| | | | | | | | F-3 | 30 | | |
| (5) | A-2 | 100 | D-2 | 7 | E-2 | 3 | F-1 | 1500 | G-1 | 5 |
| | | | | | | | F-2 | 625 | | |
| | | | | | | | F-3 | 30 | | |

Each component shown in Table 1 is as follows.

### Acid Generator (D)

(D-1): 4-cyclohexylphenyldiphenylsulfonium nonafluorobutanesulfonate
(D-2): triphenylsulfonium nonafluoro-n-butanesulfonate
(D-3): triphenylsulfonium 2-bicyclo[2.2.1]hept-2-yl-1,1-difluoroethanesulfonate

### Acid Diffusion Controller (E)

(E-1): (R)-(+)-1-(t-butoxycarbonyl)-2-pyrrolidinemethanol N-t-butoxycarbonylpyrrolidine
(E-2): triphenylsulfonium salicylate

### Solvent (F)

(F-1): propylene glycol monoethyl ether acetate
(F-2): cyclohexanone
(F-3): γ-butyrolactone

### Synthesis Example 4

60.13 g of p-hydroxymethacrylanilide (monomer), 39.87 g of p-t-butoxystyrene (monomer), and 10.42 g of dimethyl 2,2′-azobisisobutyrate (radical initiator) were dissolved in 600 g of isopropyl alcohol (IPA). The monomers were polymerized for 6 hours under reflux conditions (82° C.). After cooling the reaction vessel with running water, 150 g of IPA was added to the reaction solution. The reaction solution was added to 4500 g of methanol with stirring to effect reprecipitation, followed by suction filtration. After repeating the above reprecipitation operation (addition of IPA to suction filtration) four times, the resulting product was dried at 50° C. under vacuum to obtain a polymer (B-1) (110 g, yield: 75%). The polymer (B-1) had an Mw of 5500 and a dispersity (Mw/Mn) of 1.5. As a result of ¹³C-NMR analysis, the polymer (B-1) was found to contain the repeating units shown by the following formula (B-1). The content (molar ratio) of the repeating units was x/y=60.0/40.0. The polymer (B-1) is referred to as “hydroxyl group-containing resin (B-1)”.

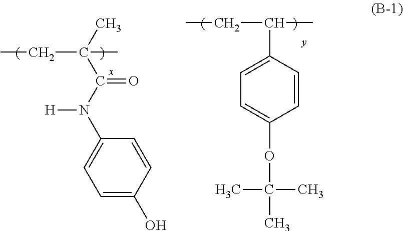

### Synthesis Example 5

A polymer (B-2) was obtained in the same manner as in Synthesis Example 4, except for using 59.69 g of p-hydroxymethacrylanilide, 33.09 g of t-butoxystyrene, and 7.21 g of 2-(((trifluoromethyl)sulfonyl)amino)ethyl-1-methacrylate (87 g, yield: 87%). The polymer (B-2) had an Mw of 5200 and a dispersity (Mw/Mn) of 1.5. As a result of ¹³C-NMR analysis, the polymer (B-2) was found to contain the repeating units shown by the following formula (B-2). The content (molar ratio) of the repeating units was x/y/z=61.0/34.0/5.0. The polymer (B-2) is referred to as “hydroxyl group-containing resin (B-2)”.

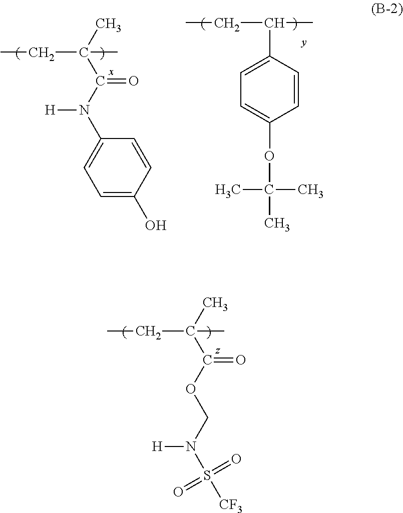

### Example 1

A mixture of 100 parts of the resin (B-1) prepared in Synthesis Example 4, 5 parts of a crosslinking agent (C-1), 30 parts of a crosslinking agent (C-3), 524 parts of a solvent (F-3), and 2096 parts of a solvent (F-4) was stirred for 3 hours, and filtered through a filter having a pore size of 0.03 μm to obtain a resist pattern coating agent (A) (hereinafter referred to as “coating agent (A)”).

### Examples 2 to 15

Resist pattern coating agents (B) to (O) were prepared in the same manner as in Example 1, except for changing the composition as shown in Table 2.

TABLE 2

| | | Hydroxyl | | | | | | | | | | | |
|---|---|---|---|---|---|---|---|---|---|---|---|---|---|
| | | group- | | | | | | | | | | | |
| | | containing | | | | | | | | | | | |
| | | resin | | Crosslinking agent (C) | | | | | | Solvent (F) | | | |
| | | | Amount | | Amount | | Amount | | Amount | | Amount | | Amount |
| | Coating | | (parts by | | (parts by | | (parts by | | (parts by | | (parts by | | (parts by |
| | agent | Type | mass) | Type | mass) | Type | mass) | Type | mass) | Type | mass) | Type | mass) |
| Example 1 | A | B-1 | 100 | C-1 | 5 | C-3 | 30 | — | — | F-3 | 524 | F-4 | 2096 |
| Example 2 | B | B-1 | 100 | C-1 | 5 | C-2 | 15 | C-4 | 15 | F-3 | 524 | F-4 | 2096 |
| Example 3 | C | B-1 | 100 | C-1 | 10 | C-2 | 25 | — | — | F-3 | 2620 | — | — |
| Example 4 | D | B-1 | 100 | C-1 | 10 | C-2 | 25 | — | — | F-3 | 524 | F-4 | 2096 |
| Example 5 | E | B-1 | 100 | C-1 | 5 | C-2 | 30 | — | — | F-3 | 2620 | — | — |
| Example 6 | F | B-1 | 100 | C-1 | 5 | C-2 | 30 | — | — | F-3 | 524 | F-4 | 2096 |
| Example 7 | G | B-1 | 100 | C-2 | 10 | C-3 | 25 | — | — | F-3 | 524 | F-4 | 2096 |
| Example 8 | H | B-1 | 100 | C-4 | 10 | C-3 | 25 | — | — | F-3 | 524 | F-4 | 2096 |
| Example 9 | 1 | B-1 | 100 | C-1 | 5 | C-2 | 15 | C-3 | 15 | F-3 | 524 | F-4 | 2096 |
| Example | J | B-1 | 100 | C-1 | 10 | C-4 | 25 | — | — | F-3 | 524 | F-4 | 2096 |
| 10 | | | | | | | | | | | | | |
| Example | K | B-1 | 100 | C-1 | 5 | C-4 | 30 | — | — | F-3 | 524 | F-4 | 2096 |
| 11 | | | | | | | | | | | | | |
| Example | L | B-2 | 100 | C-1 | 5 | C-2 | 30 | — | — | F-3 | 524 | F-4 | 2096 |
| 12 | | | | | | | | | | | | | |
| Example | M | B-2 | 100 | C-1 | 10 | C-4 | 25 | — | — | F-3 | 524 | F-4 | 2096 |
| 13 | | | | | | | | | | | | | |
| Example | N | B-1 | 100 | C-2 | 35 | — | — | — | — | F-3 | 524 | F-4 | 2096 |
| 14 | | | | | | | | | | | | | |
| Example | O | B-1 | 100 | C-4 | 35 | — | — | — | — | F-3 | 524 | F-4 | 2096 |
| 15 | | | | | | | | | | | | | |

Each component shown in Table 2 is as follows.

### Crosslinking Agent (C)

(C-1): Nikalac MX-750 (manufactured by Nippon Carbide Industries Co., Inc.)
(C-2): pentaerythritol tetracrylate
(C-3): OXIPA (manufactured by Ube Industries, Ltd.)
(C-4): pentaerythritol triacrylate

### Solvent (F)

(F-3): 1-butanol
(F-4): 4-methyl-2-pentanol

### Reference Example 1

A lower-layer antireflective film composition (“ARC29A” manufactured by Brewer Science) was spin-coated onto a 12-inch silicon wafer using a coater/developer “CLEAN TRACK ACT12” (manufactured by Tokyo Electron Ltd.), and prebaked (PB) (205° C., 60 sec) to form a film (thickness: 77 nm). The resist material (1) was spin-coated onto the film using the coater/developer “CLEAN TRACK ACT 12”, prebaked (PB) (120° C., 60 sec), and cooled (23° C., 30 sec) to obtain a first resist layer (thickness: 150 nm). The first resist layer was exposed through a mask (50 nm line/200 nm pitch) using an ArF liquid immersion lithography system (“XT1250i” manufactured by ASML) (NA: 0.85, Outer/Inner=0.89/0.59, Annular). The first resist layer was subjected to PEB (115° C., 60 sec) on the hot plate of the coater/developer “CLEAN TRACK ACT12”, cooled (23° C., 30 sec), subjected to paddle development (30 sec) using a 2.38% tetramethylammonium hydroxide aqueous solution (hereinafter referred to as “TMAH aqueous solution”) (using the LD nozzle of the development cup), and rinsed with ultrapure water. The wafer was then spin-dried at 2000 rpm for 15 seconds to obtain an evaluation substrate A on which a first resist pattern (50 nm line/200 nm pitch resist pattern) was formed.

The coating agent (A) was spin-coated onto the first resist pattern formed on the evaluation substrate A to a thickness of 150 nm using the coater/developer “CLEAN TRACK ACT12”, and prebaked (PB) (130° C., 60 sec). The resulting film was cooled on a cooling plate (23° C., 30 sec) using the coater/developer “CLEAN TRACK ACT12”, subjected to paddle development (60 sec) using a 2.38% TMAH aqueous solution (using the LD nozzle of the development cup), and rinsed with ultrapure water. The substrate was spin-dried at 2000 rpm for 15 seconds, and subjected to PEB (150° C., 60 sec) to obtain an evaluation substrate B1 on which an insolubilized resist pattern was formed. The pattern formed on the evaluation substrate B1 was evaluated as “Good”, and the pattern dimensional change was evaluated as “Excellent”.

### Reference Examples 2 to 26

An evaluation substrate B was obtained in the same manner as in Reference Example 1, except for forming the insolubilized resist pattern under conditions shown in Tables 3-1 and 3-2 using an evaluation substrate A obtained in the same manner as in Reference Example 1. The evaluation results for each evaluation substrate B are shown in Tables 3-1 and 3-2. Note that the first resist pattern formed on the evaluation substrate A used in Reference Examples 19 to 23 was a 180 nm line/240 nm pitch resist pattern, and the first resist pattern formed on the evaluation substrate A used in Reference Example 24 was a 50 nm space/200 nm pitch resist pattern.

TABLE 3-1

| | Insolubilized resist pattern-forming conditions | | | | | | | | | | | |
|---|---|---|---|---|---|---|---|---|---|---|---|---|
| | | | | | | | | Baking or UV cure | | | | |
| | | Baking or UV cure (before | | | Baking or UV cure | | | (after washing | | Evalu- | Pattern | |
| | | washing) | | | (after washing (first)) | | | (second)) | | ation | dimen- | Evaluation |
| | Coating | Temperature | UV lamp | Time | Temperature | UV lamp | Time | Temperature | Time | of | sional | substrate |
| | agent | (° C.) | (wavelength) | (s) | (° C.) | (wavelength) | (s) | (° C.) | (s) | pattern | change | B |
| Reference | A | 130 | — | 60 | 150 | — | 60 | — | — | Good | Excellent | B1 |
| Example 1 | | | | | | | | | | | | |
| Reference | B | 130 | — | 60 | 150 | — | 60 | — | — | Good | Excellent | B2 |
| Example 2 | | | | | | | | | | | | |
| Reference | C | 130 | — | 60 | 150 | — | 60 | — | — | Good | Excellent | B3 |
| Example 3 | | | | | | | | | | | | |
| Reference | D | 130 | — | 60 | 150 | — | 60 | — | — | Good | Excellent | B4 |
| Example 4 | | | | | | | | | | | | |
| Reference | E | 130 | — | 60 | 150 | — | 60 | — | — | Good | Excellent | B5 |
| Example 5 | | | | | | | | | | | | |
| Reference | F | 130 | — | 60 | 150 | — | 60 | — | — | Good | Excellent | B6 |
| Example 6 | | | | | | | | | | | | |
| Reference | G | 130 | — | 60 | 150 | — | 60 | — | — | Good | Excellent | B7 |
| Example 7 | | | | | | | | | | | | |
| Reference | H | 130 | — | 60 | 150 | — | 60 | — | — | Good | Excellent | B8 |
| Example 8 | | | | | | | | | | | | |
| Reference | I | 130 | — | 60 | 150 | — | 60 | — | — | Good | Excellent | B9 |
| Example 9 | | | | | | | | | | | | |
| Reference | J | 130 | — | 60 | 150 | — | 60 | — | — | Good | Excellent | B10 |
| Example 10 | | | | | | | | | | | | |
| Reference | K | 130 | — | 60 | 150 | — | 60 | — | — | Good | Excellent | B11 |
| Example 11 | | | | | | | | | | | | |
| Reference | L | 130 | — | 60 | 150 | — | 60 | — | — | Good | Excellent | B12 |
| Example 12 | | | | | | | | | | | | |
| Reference | M | 130 | — | 60 | 150 | — | 60 | — | — | Good | Excellent | B13 |
| Example 13 | | | | | | | | | | | | |

TABLE 3-2

| | Insolubilized resist pattern-forming conditions | | | | | | | | | | | |
|---|---|---|---|---|---|---|---|---|---|---|---|---|
| | | | | | | | | Baking or UV cure | | | | |
| | | Baking or UV cure (before | | | Baking or UV cure | | | (after washing | | Evalu- | Pattern | |
| | | washing) | | | (after washing (first)) | | | (second)) | | ation | dimen- | Evaluation |
| | Coating | Temperature | UV lamp | Time | Temperature | UV lamp | Time | Temperature | Time | of | sional | substrate |
| | agent | (° C.) | (wavelength) | (s) | (° C.) | (wavelength) | (s) | (° C.) | (s) | pattern | change | B |
| Reference | I | 115 | — | 60 | 130 | — | 60 | 150 | 60 | Good | Excellent | B14 |
| Example 14 | | | | | | | | | | | | |
| Reference | G | 120 | — | 60 | 135 | — | 90 | 160 | 90 | Good | Excellent | B15 |
| Example 15 | | | | | | | | | | | | |
| Reference | E | 130 | — | 60 | 150 | — | 60 | — | — | Good | Excellent | B16 |
| Example 16 | | | | | | | | | | | | |
| Reference | E | 130 | — | 60 | 150 | — | 60 | — | — | Good | Excellent | B17 |
| Example 17 | | | | | | | | | | | | |
| Reference | E | 130 | — | 60 | 150 | — | 60 | — | — | Good | Excellent | B18 |
| Example 18 | | | | | | | | | | | | |
| Reference | G | 150 | — | 60 | — | — | — | — | — | Good | Good | B19 |
| Example 19 | | | | | | | | | | | | |
| Reference | G | 130 | — | 60 | 150 | — | 90 | — | — | Good | Excellent | B20 |
| Example 20 | | | | | | | | | | | | |
| Reference | G | — | Xe₂ | 60 | — | — | — | — | — | Good | Good | B21 |
| Example 21 | | | (172 nm) | | | | | | | | | |
| Reference | G | 130 | — | 60 | — | Xe₂ | 60 | — | — | Good | Excellent | B22 |
| Example 22 | | | | | | (172 nm) | | | | | | |
| Reference | E | 130 | — | 60 | 150 | — | 60 | — | — | Good | Excellent | B23 |
| Example 23 | | | | | | | | | | | | |
| Reference | E | 130 | | 60 | 150 | — | 60 | — | — | Good | Excellent | B24 |
| Example 24 | | | | | | | | | | | | |
| Reference | N | 130 | — | 60 | 150 | — | 60 | — | — | Good | Excellent | B25 |
| Example 25 | | | | | | | | | | | | |
| Reference | O | 130 | — | 60 | 150 | — | 60 | — | — | Good | Excellent | B26 |
| Example 26 | | | | | | | | | | | | |

### Example 16

The resist material (2) was spin-coated onto the insolubilized resist pattern of the evaluation substrate B1 obtained in Reference Example 1 using the coater/developer “CLEAN TRACK ACT12”, prebaked (PB) (100° C., 60 sec), and cooled (23° C., 30 sec) to obtain a second resist layer (thickness: 150 nm). The space area of the insolubilized resist pattern was exposed through a mask (50 nm line/200 nm pitch) using the ArF liquid immersion lithography system (NA: 0.85, Outer/Inner=0.89/0.59, Annular). The film was subjected to PEB (95° C., 60 sec) on the hot plate of the coater/developer “CLEAN TRACK ACT12”, cooled (23° C., 30 sec), subjected to paddle development (30 sec) using a 2.38% TMAH aqueous solution (using the LD nozzle of the development cup), and rinsed with ultrapure water. The substrate was then spin-dried at 2000 rpm for 15 seconds to obtain an evaluation substrate C on which a second resist pattern was formed.

### Examples 17 to 41

An evaluation substrate C on which a second resist pattern was formed was obtained in the same manner as in Example 16, except for forming the second resist layer using the evaluation substrate B and the resist material as shown in Table 4. The evaluation results for each evaluation substrate C are shown in Table 4.

### Comparative Examples 1 and 2

An evaluation substrate C was obtained in the same manner as in Example 16, except that the evaluation substrate A that was not treated with the insolubilizing resin composition was used, and the second resist pattern was formed on the first resist pattern under conditions shown in Table 4. The evaluation results for each evaluation substrate C are shown in Table 4.

TABLE 4

| | | Second resist pattern-forming conditions | | | | | |
|---|---|---|---|---|---|---|---|
| | | | PB conditions | | PEB conditions | | |
| | Evaluation | | Temperature | | Temperature | | Evaluation of |
| | substrate | Resist material | (° C.) | Time (s) | (° C.) | Time (s) | pattern |
| Example 16 | B1 | (2) | 100 | 60 | 95 | 60 | Good |
| Example 17 | B2 | (2) | 100 | 60 | 95 | 60 | Good |
| Example 18 | B3 | (2) | 100 | 60 | 95 | 60 | Good |
| Example 19 | B4 | (2) | 100 | 60 | 95 | 60 | Good |
| Example 20 | B5 | (2) | 100 | 60 | 95 | 60 | Good |
| Example 21 | B6 | (2) | 100 | 60 | 95 | 60 | Good |
| Example 22 | B7 | (2) | 100 | 60 | 95 | 60 | Good |
| Example 23 | B8 | (2) | 100 | 60 | 95 | 60 | Good |
| Example 24 | B9 | (2) | 100 | 60 | 95 | 60 | Good |
| Example 25 | B10 | (2) | 100 | 60 | 95 | 60 | Good |
| Example 26 | B11 | (2) | 100 | 60 | 95 | 60 | Good |
| Example 27 | B12 | (2) | 100 | 60 | 95 | 60 | Good |
| Example 28 | B13 | (2) | 100 | 60 | 95 | 60 | Good |
| Example 29 | B14 | (2) | 100 | 60 | 95 | 60 | Good |
| Example 30 | B15 | (2) | 100 | 60 | 95 | 60 | Good |
| Example 31 | B16 | (3) | 100 | 60 | 95 | 60 | Good |
| Example 32 | B17 | (4) | 100 | 60 | 95 | 60 | Good |
| Example 33 | B18 | (5) | 100 | 60 | 95 | 60 | Good |
| Example 34 | B19 | (2) | 100 | 60 | 95 | 60 | Good (hole) |
| Example 35 | B20 | (2) | 100 | 60 | 95 | 60 | Good (hole) |
| Example 36 | B21 | (2) | 100 | 60 | 95 | 60 | Good (hole) |
| Example 37 | B22 | (2) | 100 | 60 | 95 | 60 | Good (hole) |
| Example 38 | B23 | (2) | 100 | 60 | 95 | 60 | Good (hole) |
| Example 39 | B24 | (2) | 100 | 60 | 95 | 60 | Good (hole) |
| Example 40 | B25 | (2) | 100 | 60 | 95 | 60 | Good |
| Example 41 | B26 | (2) | 100 | 60 | 95 | 60 | Good |
| Comparative | A | (1) | 120 | 60 | 115 | 60 | Bad |
| Example 1 | | | | | | | |
| Comparative | A | (2) | 100 | 60 | 95 | 60 | Bad |
| Example 2 | | | | | | | |

As shown in Table 4, two resist patterns can be efficiently formed on a substrate by utilizing the resist pattern coating agent according to one embodiment of the invention.

The resist pattern-forming method according to one embodiment of the invention can effectively and accurately reduce the space of the resist pattern, and can advantageously and economically form a pattern that exceeds the wavelength limit of an exposure system. Therefore, the resist pattern-forming method according to one embodiment of the invention may suitably be used in the field of microfabrication such as production of integrated circuit devices that are expected to be further scaled down in the future.

The above resist pattern coating agent according to the embodiment may suitably used for a resist pattern-forming method that can conveniently and efficiently form a fine resist pattern.

The above resist pattern-forming method according to the embodiment can conveniently and efficiently form a fine resist pattern.

Obviously, numerous modifications and variations of the present invention are possible in light of the above teachings. It is therefore to be understood that within the scope of the appended claims, the invention may be practiced otherwise than as specifically described herein.

1. A resist pattern coating agent comprising:
a hydroxyl group-containing resin;
a solvent; and
at least two of compounds including at least two groups shown by a following formula (1), compounds including a group shown by a following formula (2), and compounds including a group shown by a following formula (4), 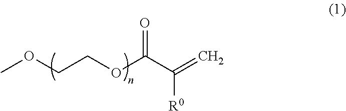
wherein R⁰ represents a hydrogen atom or a methyl group, and n is an integer from 0 to 10, 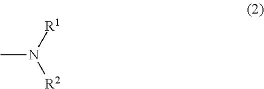
wherein R¹ and R² represent a hydrogen atom or a group shown by a following formula (3), provided that at least one of R¹ and R² represents a group shown by a formula (3), 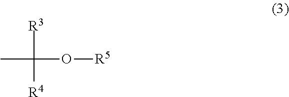
wherein R³ and R⁴ represent a hydrogen atom, an alkyl group having 1 to 6 carbon atoms, or an alkoxyalkyl group having 1 to 6 carbon atoms, or bond to form a ring having 2 to 10 carbon atoms, and R⁵ represents a hydrogen atom or an alkyl group having 1 to 6 carbon atoms, 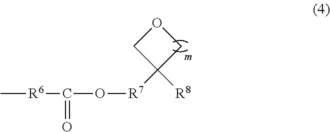
wherein each of R⁶ and R⁷ represents at least one of a single bond, a methylene group, a linear or branched alkylene group having 2 to 10 carbon atoms, and a divalent cyclic hydrocarbon group having 3 to 20 carbon atoms, R⁸ represents a linear or branched alkyl group having 1 to 10 carbon atoms or a monovalent cyclic hydrocarbon group having 3 to 20 carbon atoms, and m is 0 or 1.

2. The resist pattern coating agent according to claim 1, wherein a compound including at least two groups shown by the formula (1) among the at least two of compounds is shown by a following formula (1-1) or (1-2), 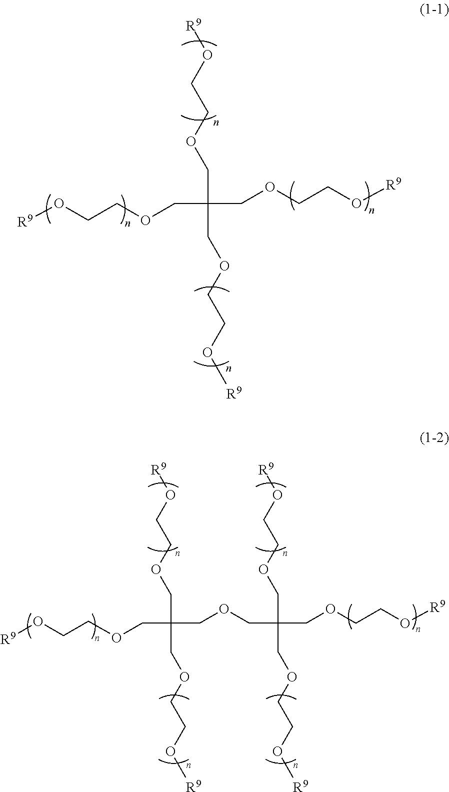
wherein n are individually an integer from 0 to 10, and each of R⁹ represents at least one of a hydrogen atom and a group shown by a following formula (5), provided that at least two of R⁹ represent a group shown by the formula (5), 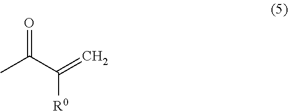
wherein R⁰ represents a hydrogen atom or a methyl group.

3. The resist pattern coating agent according to claim 1, wherein a compound including a group shown by the formula (2) among the at least two of compounds is shown by a following formula (2-1), 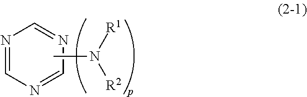
wherein R¹ and R² represent a hydrogen atom or a group shown by a following formula (3), provided that at least one of R¹ and R² represents a group shown by the formula (3), and p is an integer from 1 to 3, 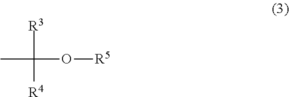
wherein R³ and R⁴ represent a hydrogen atom, an alkyl group having 1 to 6 carbon atoms, or an alkoxyalkyl group having 1 to 6 carbon atoms, or bond to form a ring having 2 to 10 carbon atoms, and R⁵ represents a hydrogen atom or an alkyl group having 1 to 6 carbon atoms.

4. The resist pattern coating agent according to claim 1, wherein a compound including a group shown by the formula (4) among the at least two of compounds is shown by a following formula (4-1), 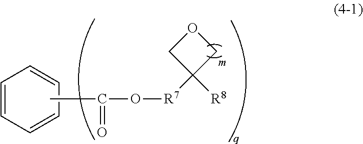
wherein R⁷ represents a single bond, a methylene group, a linear or branched alkylene group having 2 to 10 carbon atoms, or a divalent cyclic hydrocarbon group having 3 to 20 carbon atoms, R⁸ represents a linear or branched alkyl group having 1 to 10 carbon atoms or a monovalent cyclic hydrocarbon group having 3 to 20 carbon atoms, m is 0 or 1, and q is an integer from 1 to 3.

5. The resist pattern coating agent according to claim 1, wherein the hydroxyl group-containing resin has been obtained by polymerizing a monomer component shown by a following formula (6), 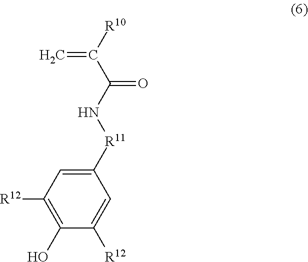
wherein each of R¹⁰ and R¹² represents at least one of a hydrogen atom and a methyl group, and R¹¹ represents a single bond or a divalent linear, branched, or cyclic hydrocarbon group.

6. The resist pattern coating agent according to claim 1, wherein the hydroxyl group-containing resin has been obtained by polymerizing a monomer component including at least one of hydroxyacrylanilide and hydroxymethacrylanilide.

7. The resist pattern coating agent according to claim 1, wherein the hydroxyl group-containing resin has been obtained by polymerizing a monomer component that further includes a monomer shown by a following formula (7), 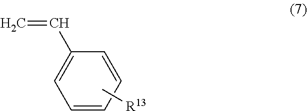
wherein R¹³ represents a hydrogen atom, an acetoxy group, a linear or branched alkyl group having 1 to 8 carbon atoms, or a linear or branched alkoxy group having 1 to 8 carbon atoms.

8. A resist pattern-forming method comprising:
providing a first positive-tone radiation-sensitive resin composition on a substrate to form a first resist pattern on the substrate;
applying the resist pattern coating agent according to claim 1 to a first resist pattern;
baking or UV-curing the resist pattern coating agent;
washing the resist pattern coating agent to form an insolubilized resist pattern that is insoluble in a developer and a second positive-tone radiation-sensitive resin composition;
providing the second positive-tone radiation-sensitive resin composition on the substrate to form a second resist layer on the substrate on which the insolubilized resist pattern is formed;
selectively exposing the second resist layer through a mask; and
developing the second resist layer to form a second resist pattern.

9. A resist pattern coating agent comprising:
a hydroxyl group-containing resin;
a solvent; and
a compound including at least two groups shown by a following formula (1), 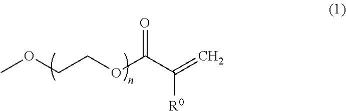
wherein R⁰ represents a hydrogen atom or a methyl group, and n is an integer from 0 to 10.

10. The resist pattern coating agent according to claim 2, wherein a compound including a group shown by the formula (2) among the at least two of compounds is shown by a following formula (2-1), 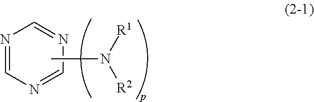
wherein R¹ and R² represent a hydrogen atom or a group shown by a following formula (3), provided that at least one of R¹ and R² represents a group shown by the formula (3), and p is an integer from 1 to 3, 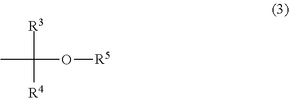
wherein R³ and R⁴ represent a hydrogen atom, an alkyl group having 1 to 6 carbon atoms, or an alkoxyalkyl group having 1 to 6 carbon atoms, or bond to form a ring having 2 to 10 carbon atoms, and R⁵ represents a hydrogen atom or an alkyl group having 1 to 6 carbon atoms.

11. The resist pattern coating agent according to claim 2, wherein a compound including a group shown by the formula (4) among the at least two of compounds is shown by a following formula (4-1), 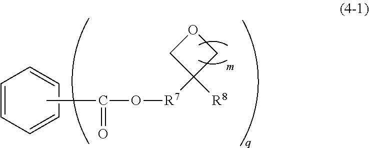
wherein R⁷ represents a single bond, a methylene group, a linear or branched alkylene group having 2 to 10 carbon atoms, or a divalent cyclic hydrocarbon group having 3 to 20 carbon atoms, R⁸ represents a linear or branched alkyl group having 1 to 10 carbon atoms or a monovalent cyclic hydrocarbon group having 3 to 20 carbon atoms, m is 0 or 1, and q is an integer from 1 to 3.

12. The resist pattern coating agent according to claim 3, wherein a compound including a group shown by the formula (4) among the at least two of compounds is shown by a following formula (4-1), 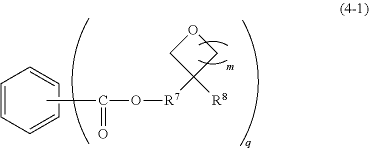
wherein R⁷ represents a single bond, a methylene group, a linear or branched alkylene group having 2 to 10 carbon atoms, or a divalent cyclic hydrocarbon group having 3 to 20 carbon atoms, R⁸ represents a linear or branched alkyl group having 1 to 10 carbon atoms or a monovalent cyclic hydrocarbon group having 3 to 20 carbon atoms, m is 0 or 1, and q is an integer from 1 to 3.

13. The resist pattern coating agent according to claim 10, wherein a compound including a group shown by the formula (4) among the at least two of compounds is shown by a following formula (4-1), 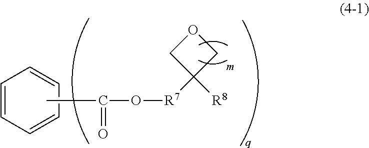
wherein R⁷ represents a single bond, a methylene group, a linear or branched alkylene group having 2 to 10 carbon atoms, or a divalent cyclic hydrocarbon group having 3 to 20 carbon atoms, R⁸ represents a linear or branched alkyl group having 1 to 10 carbon atoms or a monovalent cyclic hydrocarbon group having 3 to 20 carbon atoms, m is 0 or 1, and q is an integer from 1 to 3.

14. The resist pattern coating agent according to claim 2, wherein the hydroxyl group-containing resin has been obtained by polymerizing a monomer component shown by a following formula (6), 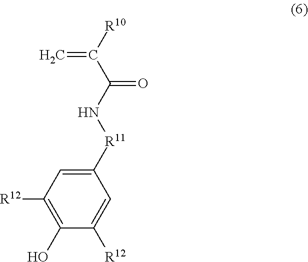
wherein each of R¹⁰ and R¹² represents at least one of a hydrogen atom and a methyl group, and R¹¹ represents a single bond or a divalent linear, branched, or cyclic hydrocarbon group.

15. The resist pattern coating agent according to claim 3, wherein the hydroxyl group-containing resin has been obtained by polymerizing a monomer component shown by a following formula (6), 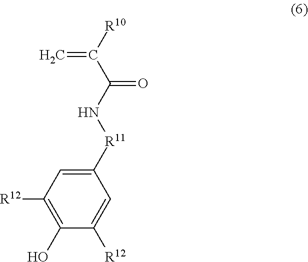
wherein each of R¹⁰ and R¹² represents at least one of a hydrogen atom and a methyl group, and R¹¹ represents a single bond or a divalent linear, branched, or cyclic hydrocarbon group.

16. The resist pattern coating agent according to claim 4, wherein the hydroxyl group-containing resin has been obtained by polymerizing a monomer component shown by a following formula (6), 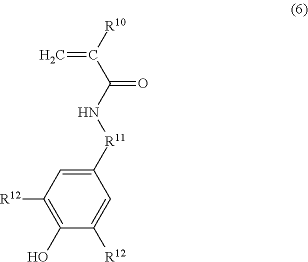
wherein each of R¹⁰ and R¹² represents at least one of a hydrogen atom and a methyl group, and R¹¹ represents a single bond or a divalent linear, branched, or cyclic hydrocarbon group.

17. The resist pattern coating agent according to claim 10, wherein the hydroxyl group-containing resin has been obtained by polymerizing a monomer component shown by a following formula (6), 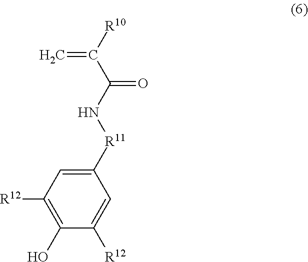
wherein each of R¹⁰ and R¹² represents at least one of a hydrogen atom and a methyl group, and R¹¹ represents a single bond or a divalent linear, branched, or cyclic hydrocarbon group.

18. The resist pattern coating agent according to claim 11, wherein the hydroxyl group-containing resin has been obtained by polymerizing a monomer component shown by a following formula (6), 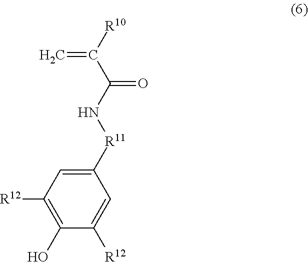
wherein each of R¹⁰ and R¹² represents at least one of a hydrogen atom and a methyl group, and R¹¹ represents a single bond or a divalent linear, branched, or cyclic hydrocarbon group.

19. The resist pattern coating agent according to claim 12, wherein the hydroxyl group-containing resin has been obtained by polymerizing a monomer component shown by a following formula (6), 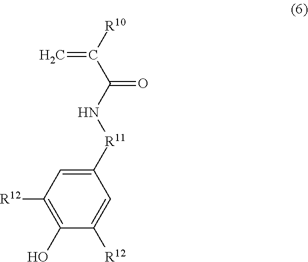
wherein each of R¹⁰ and R¹² represents at least one of a hydrogen atom and a methyl group, and R¹¹ represents a single bond or a divalent linear, branched, or cyclic hydrocarbon group.

20. The resist pattern coating agent according to claim 13, wherein the hydroxyl group-containing resin has been obtained by polymerizing a monomer component shown by a following formula (6), 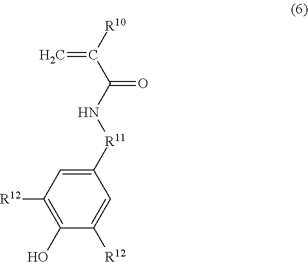
wherein each of R¹⁰ and R¹² represents at least one of a hydrogen atom and a methyl group, and R¹¹ represents a single bond or a divalent linear, branched, or cyclic hydrocarbon group.
